(19) United States
(12) Patent Application Publication
(10) Pub. No.: US 2024/0304645 A1
(43) Pub. Date: Sep. 12, 2024

(54) SPECTRUM CHIP AND MANUFACTURING METHOD THEREFOR, AND SPECTRUM ANALYSIS DEVICE

(71) Applicant: BEIJING SEETRUM TECHNOLOGY CO., LTD., Beijing (CN)

(72) Inventors: Hong ZHANG, Beijing (CN); Zhilei HUANG, Beijing (CN); Yu WANG, Beijing (CN); Qiujun QIN, Beijing (CN)

(73) Assignee: BEIJING SEETRUM TECHNOLOGY CO., LTD., Beijing (CN)

(21) Appl. No.: 18/275,275

(22) PCT Filed: Jan. 27, 2022
(86) PCT No.: PCT/CN2022/074239

§ 371 Date: Aug. 1, 2023

(30) Foreign Application Priority Data
Feb. 1, 2021 (CN) 202110136746.5
Jul. 16, 2021 (CN) 202110808927.8
Jul. 16, 2021 (CN) 202110808931.4
Jul. 16, 2021 (CN) 202121623561.9
Jul. 19, 2021 (CN) 202110815321.7

(51) Int. Cl. H01L 27/146; G01J 3/28

(52) U.S. Cl. CPC H01L 27/14625; H01L 27/14618; H01L 27/14685; G01J 3/2823

(57) ABSTRACT

The present application provides a spectrum chip and a method for manufacturing it, and a spectrum analysis device. The method for manufacturing the spectrum chip includes: forming at least one light modulation structure on a substrate to obtain a modulation unit; and coupling the modulation unit to a sensing unit, so that the modulation unit is held on a photosensitive path of the sensing unit to obtain the spectrum chip. In this way, the process of forming the light modulation structure is transferred to be performed on the substrate, so as to get rid of the limitation of the existing manufacturing process of the spectrum chip limited by a fab on the one hand, and on the other hand to ensure that the a manufacturing site will not be polluted during the manufacturing process.

### TECHNICAL FIELD

The present application relates to the technical field of spectrum chips, and more particularly, to a spectrum chip, a method for manufacturing it, and a spectrum analysis device, in which in the method for manufacturing the spectrum chip, the process of forming a light modulation structure is transferred to be performed on a substrate, so as to get rid of the limitation of the existing manufacturing process of the spectrum chip limited by a fab on the one hand, and on the other hand to ensure that the spectrum chip will not be polluted during the manufacturing process.

### BACKGROUND ART

The interaction between light and matter, such as absorption, scattering, fluorescence, raman, etc., will produce a specific spectrum, and the spectrum of each substance is unique. Therefore, spectrum information may be said to be the “fingerprint” of all things.

The spectrometer can directly detect the spectrum information of the substance to obtain the existence state and composition of the detected target, and is one of the important testing instruments in the fields of material characterization and chemical analysis. From the perspective of technological development, miniature spectrometers may be divided into four categories: dispersion type, narrowband filter type, Fourier transform type and computational reconstruction type.

With the development of computer technology, the computational reconstruction spectrometer has flourished as an emerging type of spectrometer in recent years, as it approximates or reconstructs the spectrum of the incident light by calculation. The computational reconstruction type of spectrometer can solve the problem of reduced detection performance due to miniaturization relatively well.

Since the computational reconstruction spectrometer belongs to an emerging technology, it encounters many technical problems and difficulties in practical applications. Finding and solving these technical problems and difficulties is the only way to promote the maturation of the computational reconstruction spectrometer. Of course, the principle of computational reconstruction may also be used for spectrum imaging devices.

In the computational reconstruction spectrometer or spectrum imaging device, the spectrum chip is the absolute core component. How to produce spectrum chips with high performance, especially to achieve mass production, is an industrial problem which is urgent to be solved.

### SUMMARY

In order to solve the above technical problems, the present application is provided. Examples of the present application provide a spectrum chip, a method for manufacturing it, and a spectrum analysis device, wherein a process of forming a light modulation structure is transferred to be performed on a substrate, so as to get rid of the limitation of the existing manufacturing process of the spectrum chip limited by a fab on the one hand, and on the other hand to ensure that the spectrum chip will not be polluted during the manufacturing process.

According to an aspect of the present application, provided is a method for manufacturing a spectrum chip, which includes: forming at least one light modulation structure on a substrate to obtain a modulation unit; and coupling the modulation unit to a sensing unit, so that the modulation unit is held on a photosensitive path of the sensing unit to obtain the spectrum chip.

In the method for manufacturing the spectrum chip according to the present application, the substrate is made of a material selected from the group consisting of silicon dioxide, aluminum oxide, acrylic, germanium, or plastic.

In the method for manufacturing the spectrum chip according to the present application, the at least one light modulation structure includes a first light modulation structure and a second light modulation structure; wherein, forming the at least one light modulation structure on the substrate to obtain the modulation unit includes: forming a first light modulation layer on the substrate; etching the first light modulation layer to form the first light modulation structure with at least one first modulation unit; forming a second light modulation layer on the first light modulation structure; and etching the second light modulation layer to form the second light modulation structure with at least one second modulation unit.

In the method for manufacturing the spectrum chip according to the present application, the at least one modulation unit includes a first light modulation structure; wherein, forming the at least one light modulation structure on the substrate to obtain the modulation unit includes: forming a first light modulation layer on the substrate; and etching the first light modulation layer to form the first light modulation structure with at least one first modulation unit.

In the method for manufacturing the spectrum chip according to the present application, forming the first light modulation layer on the substrate includes: depositing the first light modulation layer on the substrate by a deposition process.

In the method for manufacturing the spectrum chip according to the present application, forming the first light modulation layer on the substrate includes: providing the first light modulation layer; and overlaying the light modulation layer on the substrate.

In the method for manufacturing the spectrum chip according to the present application, forming the second light modulation layer on the first light modulation structure includes: forming a connection layer on the first light modulation layer; and forming the second light modulation layer on the connection layer.

In the method for manufacturing the spectrum chip according to the present application, coupling the modulation unit to the sensing unit, so that the modulation unit is held on the photosensitive path of the sensing unit to obtain the spectrum chip includes: coupling the modulation unit to the sensing unit in a flip-chip manner, wherein at least one light modulation structure of the modulation unit is overlaid on the sensor.

In the method for manufacturing the spectrum chip according to the present application, coupling the modulation unit to the sensing unit in the flip-chip manner includes: forming a dielectric layer on the sensing unit; and coupling the modulation unit to the dielectric layer.

In the method for manufacturing the spectrum chip according to the present application, coupling the modulation unit to the dielectric layer includes: forming a binding layer on the at least one light modulation structure of the modulation unit; and coupling the modulation unit to the dielectric layer in a manner that the binding layer is bound to the dielectric layer.

In the method for manufacturing the spectrum chip according to the present application, the dielectric layer and the binding layer are made of same material.

In the method for manufacturing the spectrum chip according to the present application, a distance between a lower surface of the light modulation structure adjacent to the sensing unit in the at least one light modulation structure and an upper surface of the dielectric layer is less than or equal to 10 um.

In the method for manufacturing the spectrum chip according to the present application, a proportion of the distance between the lower surface of the light modulation structure adjacent to the sensing unit in the at least one light modulation structure and the upper surface of the dielectric layer exceeding a predetermined threshold is less than or equal to 10%.

In the method for manufacturing the spectrum chip according to the present application, a difference in distances between respective corresponding positions on the lower surface of the light modulation structure adjacent to the sensing unit in the at least one light modulation structure and the upper surface of the dielectric layer is less than ±5-10 um.

In the method for manufacturing the spectrum chip according to the present application, the sensing unit includes at least one pixel and a logic circuit layer electrically connected to the at least one pixel.

In the method for manufacturing the spectrum chip according to the present application, the light modulation structure includes a modulation portion and a non-modulation portion.

In the method for manufacturing the spectrum chip according to the present application, the modulation portion includes at least one light modulation unit, and the non-modulation portion includes at least one filter unit.

In the method for manufacturing the spectrum chip according to the present application, forming the at least one light modulation structure on the substrate to obtain the modulation unit includes: forming a light modulation layer on the substrate; forming the modulation portion in a part of region of the light modulation layer; and forming the non-modulation portion in other part of the region of the light modulation layer.

In the method for manufacturing the spectrum chip according to the present application, forming the at least one light modulation structure on the substrate to obtain the modulation unit includes: forming a first material region and a second material region on the substrate; processing the first material region to form the modulation portion; and processing the second material region to form the non-modulation portion.

In the method for manufacturing the spectrum chip according to the present application, the first material region and the second material region have same thickness.

In the method for manufacturing the spectrum chip according to the present application, forming the light modulation layer on the substrate includes: depositing the light modulation layer on the substrate by a deposition process.

In the method for manufacturing the spectrum chip according to the present application, forming the first material region and the second material region on the substrate includes: depositing the first material region and the second material region on the substrate by a deposition process.

In the method for manufacturing the spectrum chip according to the present application, coupling the modulation unit to the sensing unit, so that the modulation unit is held on the photosensitive path of the sensing unit to obtain the spectrum chip includes: coupling the modulation unit to the sensing unit in a flip-chip manner, wherein at least one light modulation structure of the modulation unit is overlaid on the sensing unit.

In the method for manufacturing the spectrum chip according to the present application, coupling the modulation unit to the sensing unit in a flip-chip manner includes: forming a dielectric layer on the sensing unit; and coupling the modulation unit to the dielectric layer.

In the method for manufacturing the spectrum chip according to the present application, coupling the modulation unit to the dielectric layer includes: forming a binding layer on the at least one light modulation structure of the modulation unit; and coupling the modulation unit to the dielectric layer in a manner that the binding layer is bound to the dielectric layer.

In the method for manufacturing the spectrum chip according to the present application, the dielectric layer and the binding layer are made of same material.

In the method for manufacturing the spectrum chip according to the present application, coupling the modulation unit to the dielectric layer includes: attaching the modulation unit to the sensing unit by an adhesive; or, attaching the modulating unit to the sensing unit by a bonding process.

In the method for manufacturing the spectrum chip according to the present application, coupling the modulation unit to the dielectric layer includes: fixing the modulation unit to the dielectric layer by a van der Waals force.

In the method for manufacturing the spectrum chip according to the present application, coupling the modulation unit to the dielectric layer includes: binding the modulation unit to the dielectric layer by an encapsulation body.

In the method for manufacturing the spectrum chip according to the present application, a distance between a lower surface of the light modulation structure adjacent to the sensing unit in the at least one light modulation structure and an upper surface of the dielectric layer is less than or equal to a length of a side of the light modulation unit.

According to another aspect of the present application, there is also provided a method for manufacturing a spectrum chip, which includes: providing a substrate; forming an array of light modulation structures including at least two light modulation structures on a substrate to obtain a modulation unit jointed panel; providing a sensing unit jointed panel which includes at least two sensing units; coupling the modulation unit jointed panel to the sensing unit jointed panel to obtain a spectrum chip jointed panel; and dividing the spectrum chip jointed panel to obtain at least two spectrum chips.

According to yet another aspect of the present application, a spectrum chip is also provided, wherein the spectrum chip is manufactured by the method for manufacturing the spectrum chip as described above.

According to yet another aspect of the present application, there is also provided a spectrum chip, which includes: a sensing unit; and a modulation unit held on a photosensitive path of the sensing unit, wherein the modulation unit includes a substrate and at least one light modulation structure formed on the substrate, and the light modulation structure is coupled to the sensing unit, and the substrate is located above the light modulation structure and is used for protecting the light modulation structure.

In the spectrum chip according to the present application, the substrate is made of a material selected from the group consisting of silicon dioxide, aluminum oxide, acrylic, germanium or plastic. In the spectrum chip according to the present application, the light modulation structure includes at least one light modulation unit, and at least part of the light modulation unit is filled with filler. In the spectrum chip according to the present application, the at least one light modulation structure includes a first light modulation structure coupled to the sensing unit and a second light modulation structure coupled to the first light modulation structure.

In the spectrum chip according to the present application, the spectrum chip further includes a connection layer disposed between the first light modulation structure and the second light modulation structure, so as to couple the second light modulation structure to the first light modulation structure by the connection layer.

In the spectrum chip according to the present application, the first light modulation structure includes at least one light modulation unit, the second light modulation structure includes at least one light modulation unit, and at least parts of the light modulation units of the first light modulation structure and/or the second light modulation structure are filled with filler.

In the spectrum chip according to the present application, the first light modulation structure and the second light modulation structure are made of material with relatively high refractive index, and the connection layer is made of material with relatively low refractive index.

In the spectrum chip according to the present application, the spectrum chip further includes a dielectric layer formed on the sensing unit, wherein the modulation unit is coupled to the sensing unit in a manner of being bound to the dielectric layer.

In the spectrum chip according to the present application, a portion of a surface of the dielectric layer for binding the modulation unit is a flat surface.

In the spectrum chip according to the present application, the spectrum chip further includes a binding layer formed on the light modulation structure, wherein the binding layer is bound to the dielectric layer so that the modulation unit is coupled to the sensing unit in the manner of being bound to the dielectric layer.

In the spectrum chip according to the present application, the dielectric layer and the binding layer are made of same material.

In the spectrum chip according to the present application, a distance between a lower surface of the light modulation structure adjacent to the sensing unit in the at least one light modulation structure and an upper surface of the dielectric layer is less than or equal to 10 um.

In the spectrum chip according to the present application, a proportion of the distance between the lower surface of the light modulation structure adjacent to the sensing unit in the at least one light modulation structure and the upper surface of the dielectric layer exceeding a preset threshold is less than or equal to 10%.

In the spectrum chip according to the present application, the light modulation structure includes at least one light modulation unit, wherein a distance between a lower surface of the light modulation structure adjacent to the sensing unit in the at least one light modulation structure and an upper surface of the dielectric layer is less than or equal to a length of a side of the light modulation unit.

In the spectrum chip according to the present application, a difference in distances between any two regions in the lower surface of the light modulation structure adjacent to the sensing unit in the at least one light modulation structure and corresponding two regions in the upper surface of the dielectric layer is less than or equal to 10 um.

In the spectrum chip according to the present application, the light modulation structure includes a modulation portion and a non-modulation portion, the modulation portion includes at least one light modulation unit, and the non-modulation portion includes at least one filter unit.

In the spectrum chip according to the present application, the filter units are arranged in an array to form a Bayer filter.

In the spectrum chip according to the present application, the spectrum chip further includes an encapsulation body for binding the modulation unit to the sensing unit.

In the spectrum chip according to the present application, the encapsulation body integrally wraps at least a part of side surface of the modulation unit and at least a part of side surface of the sensing unit.

In the spectrum chip according to the present application, the modulation unit and the sensing unit are bound with each other by a van der Waals force under the action of the encapsulation body.

According to another aspect of the present application, there is also provided a spectrum analysis device, which includes: a circuit board; and a spectrum chip manufactured by the above-mentioned method for manufacturing the spectrum chip, wherein the spectrum chip is electrically connected to the circuit board.

In the spectrum analysis device according to an example of the present application, the spectrum analysis device further includes: an optical component held on a photosensitive path of the spectrum chip.

In the spectrum analysis device according to an example of the present application, the spectrum analysis device further includes an encapsulation body disposed on the circuit board, wherein the encapsulation body is integrally formed on the circuit board and wraps at least a part of outer surface of the spectrum chip.

In the spectrum analysis device according to an example of the present application, the encapsulation body is made of opaque material.

In the spectrum chip and the method for manufacturing it and the spectrum analysis device provided by the present application, the process of forming the light modulation structure is transferred to be performed on the substrate, so as to get rid of the limitation of the existing manufacturing process of the spectrum chip limited by a fab on the one hand, and on the other hand to ensure that the spectrum chip will not be polluted during the manufacturing process.

### BRIEF DESCRIPTION OF THE DRAWINGS

Various other advantages and benefits of the present application will become apparent to those of ordinary skill in the art upon reading the following detailed description of the preferred examples. The accompanying drawings are for the purpose of illustrating the preferred examples only, and are not to be considered as limitations on the present application. Obviously, the drawings described below are only some examples of the present application, and for those of ordinary skill in the art, other drawings can also be obtained from these drawings without any creative effort. Also, the same components are denoted by the same reference numerals throughout the drawings.

FIG. 1 illustrates a schematic diagram of a spectrum chip according to an example of the present application.

FIG. 2 illustrates a block diagram of the spectrum chip according to an example of the present application.

FIG. 3 illustrates a block diagram of a variant implementation of the spectrum chip according to an example of the present application.

FIG. 4 illustrates a block diagram of another variant implementation of the spectrum chip according to an example of the present application.

FIG. 5 illustrates a block diagram of yet another variant implementation of the spectrum chip according to an example of the present application.

FIGS. 6A to 6C illustrates schematic diagrams of a method for manufacturing the spectrum chip according to an example of the present application.

FIGS. 7A to 7C illustrates schematic diagrams a method for manufacturing a jointed panel of the spectrum chip according to an example of the present application.

FIG. 8 illustrates a block diagram of a spectrum analysis device according to an example of the present application.

FIG. 9 illustrates a schematic diagram of a variant implementation of the spectrum chip according to an example of the present application.

FIG. 10 illustrates a schematic diagram of a photosensitive component according to an example of the present application.

FIG. 11 illustrates a schematic diagram of a variant implementation of the photosensitive component according to an example of the present application.

FIG. 12 illustrates a schematic diagram of a spectrum chip according to an example of the present application.

FIG. 13 illustrates a block diagram of the spectrum chip according to an example of the present application.

FIG. 14 illustrates a schematic cross-sectional view of a light modulation structure according to an example of the application.

FIGS. 15A to 15C illustrate schematic diagrams of a method for manufacturing the spectrum chip according to an example of the present application.

FIGS. 16A to 16C illustrate schematic diagrams of a method for manufacturing a jointed panel of the spectrum chip according to an example of the present application.

FIG. 17 illustrates a block diagram of a spectrum analysis device according to an example of the present application.

FIG. 18 illustrates a schematic diagram of a variant implementation of the spectrum chip according to an example of the present application.

FIG. 19 illustrates a schematic diagram of a photosensitive component according to an example of the present application.

FIG. 20 illustrates a schematic diagram of a variant implementation of the photosensitive component according to an example of the present application.

### DETAILED DESCRIPTION

Hereinafter, exemplary examples according to the present application will be described in detail with reference to the accompanying drawings. Obviously, the described examples are only a part of the examples of the present application, rather than all the examples of the present application, and it should be understood that the present application is not limited by the exemplary examples described herein.

### Application Overview

As mentioned above, since the computational reconstruction spectrometer belongs to an emerging technology, it encounters many technical problems and difficulties in practical applications. Finding and solving these technical problems and difficulties is the only way to promote the maturation of the computational reconstruction spectrometer. Of course, the principle of computational reconstruction may also be used for spectrum imaging devices.

In the computational reconstruction spectrometer or spectrum imaging device, the spectrum chip is the absolute core component. How to produce spectrum chips with high performance, especially to achieve mass production, is an industrial problem which is urgent to be solved.

In order to achieve mass production, the spectrum chip is manufactured by the following manufacturing process. Firstly, a layer of a light modulation layer material is deposited on an existing image sensor (e.g., CMOS image sensor, CCD sensor); then, the light modulation layer material is etched, nanoimprinted, etc. to form the light modulation layer. However, this manufacturing process may have problems in practical industrial implementation.

Specifically, the manufacturing process needs be processed on the wafer of chip, and thus it is necessary to provide product lines and production teams that match wafer-level processing, which will lead to an increase in costs on the one hand, and will be difficult for be implemented in industry due to the monopoly of the wafer processing technology on the other hand. In addition, the process of depositing the light modulation layer structure according to the characteristics of the material needs to be carried out under certain high temperature conditions, but the high temperature may cause damage to the wafer. Conversely, considering the heat resistance of the wafer, compromises must be made in the selection of the light modulation layer material, which will result in the light modulation layer not reaching the optimum performance due to the selection of the material. In addition, since the image sensor contains a logic circuit, metal powders in the logic circuit may fall and cause contamination to the entire production line under certain circumstances.

In view of the above technical difficulties, the inventors of the present application tried to transfer the process of forming the light modulation structure to be performed on the substrate, so as to, on the one hand, get rid of the limitation of the existing manufacturing process of the spectrum chip limited by the fab, and on the other hand to ensure that no contamination of metal powders occurs during the manufacturing process. That is, the modulation unit of the spectrum chip is firstly formed on the substrate and then coupled to the sensor. In this way, the problem that current manufacturing process of the spectrum chip is limited by the fab is solved. Moreover, since the modulation unit does not include a logic circuit, no contamination of metal powders and the like occur during the manufacturing process and further it can be ensured that no contamination occurs during processing process. At the same time, it can avoid high temperature affecting the performance of the sensor. In order to avoid ambiguity, this application further describes the wafer, which can be understood as a wafer or a die, that is, a sensor such as a CMOS sensor or a CCD sensor can be obtained by processing on the wafer.

Based on this, the present application proposes a method for manufacturing a spectrum chip, which includes the steps of: providing a substrate; forming at least one light modulation structure on the substrate to obtain a modulation unit; providing a sensing unit; and coupling the modulation unit to the sensing unit, so that the modulation unit is held on a photosensitive path of the sensing unit to obtain the spectrum chip. Correspondingly, the present application also proposes a spectrum chip, which is manufactured by the above-mentioned special manufacturing process.

After introducing the basic principle of the present application, various non-limiting examples of the present application will be described in detail below with reference to the accompanying drawings.

### Schematic Spectrum Chip

Spectrum chips according to examples of the present application are interpreted, wherein the spectrum chips are generally applied to computational spectrum devices. The computational spectrum devices may be spectrometers or spectrum imaging devices. Taking spectrometers as an example, the most significant difference between computational spectrometers and traditional spectrometers is the difference in filtering. In conventional spectrometers, the filters used for wavelength selection are bandpass filters. The higher the spectrum resolution is, the filters with the narrower and more passband must be used, which increases the volume and complexity of the entire system. At the same time, when the spectrum response curve is narrowed, the luminous flux decreases, resulting in a lower signal-to-noise ratio.

For a specific computational spectrometer, each filter generally adopts a broad-spectrum filter, which makes the raw data detected by the computational spectrometer system quite different from the original spectrum. However, by applying a computational reconstruction algorithm, the original spectrum can be recovered computationally. Because broadband filters pass more light through than narrowband filters, i.e. light loses less energy, the type of computational spectrometers can detect spectra from darker scenes. In addition, according to the compressed sensing theory, the spectrum curve of the filter may be appropriately designed to recover the sparse spectrum with high probability, and the number of filters is much smaller than the desired number of spectrum channels (recovering higher-dimensional vectors from lower-dimensional vectors), which is undoubtedly very conducive to miniaturization. On the other hand, by using a larger number of filters, a regularization algorithm (a denoised lower dimensional vector is obtained from a higher dimensional vector) may be used to reduce noise, which increases the signal-to-noise ratio and makes the entire system have better robustness.

Relatively speaking, when designing the traditional spectrometer, it needs to design the filter according to the required wavelength, so that the light of a specific wavelength can pass through. That is, during designing the traditional spectrometer, it needs to focus on controlling the size and positional accuracy of the light modulation structure, and at the same time, it is necessary to find a way to improve the transmittance of specific wavelengths. As for the computational spectrometer, incident light in a wide range of waveband (for example, 350 nm to 1000 nm) can be received. The incident light is modulated by the filter and then received by the sensor. When the transmission spectrum corresponding to the filter is more complex, the recovery effect of the corresponding incident light will be better.

As mentioned above, the spectrum chip according to the example of the present application is manufactured by a specific method. Before discussing the method for manufacturing the spectrum chip, the structure and working principle of the spectrum chip are explained.

The spectrum chip includes a sensing unit and a modulation unit held on a photosensitive path of the sensing unit, wherein, in particular, the modulation unit includes a substrate and at least one light modulation structure formed on the substrate, the light modulation structure includes at least one light modulation unit, the light modulation unit may be a modulation hole, a modulation column, a modulation line, etc., for modulating the incident light signal entering the sensing unit to generate a modulation signal.

In some examples of the present application, in order to facilitate binding the sensing unit to the modulation unit, the spectrum chip further includes a dielectric layer formed on the sensing unit. In this example, the dielectric layer is formed on the surface of the sensing unit, and the modulation unit is affixed to the upper surface of the dielectric layer. Correspondingly, preferably, the part of the upper surface of the dielectric layer for affixing the modulation unit is a flat surface. Preferably, the difference of refractive index between two adjacent layers in the dielectric layer, the light modulation structure and the substrate is relatively large, for example, the refractive index of the dielectric layer is low, the refractive index of the light modulation structure is high, and the refractive index of the substrate is low. It is worth noting that the dielectric layer involved in the present application can be a structure integrally formed on the sensing unit, that is, it is an inherent part of the sensing unit; of course, the dielectric layer may also be formed on the sensing unit by subsequent processing.

The working principle of the spectrum chip is briefly introduced below.

The incident light signal is set as a vector X=[X₁, X₂, . . . . X_{N}]^{T}, and the signal received by the sensing unit is set as a vector Y=[Y₁, Y₂, . . . . Y_{M}]^{T}, accordingly, Y=DX+W, wherein the transformation matrix D is determined by the light modulation structure, and the vector W is noise. In the practical application of the spectrum chip, it is necessary to calibrate the spectrum chip firstly to obtain the transformation matrix D, and then use the calibrated spectrum chip to measure the spectrum information of the measured target, that is, the known transformation matrix D and the vector Y obtained by the pixel structure are used to solve the spectrum signal X of the measured target. For traditional spectrometers, its implementation modes include spectral splitting using spectroscopic element, or filtering using narrow-band filters. Under these modes, the spectrum accuracy that can be achieved is directly related to the fineness of the physical spectroscopy, so there are great requirements for the optical path length of the physical device and the robustness of mechanical processing, which makes the high-precision spectrometer larger in volume, more expensive in cost and difficult to achieve large-scale mass production. For the computational reconstruction spectrometer, after rich spectrum information is obtained by physical devices, it is analyzed by algorithms. This method is expected to achieve a high level in terms of volume, cost, mass productivity and accuracy at the same time. In order to obtain the spectral information of the light to be measured, the spectrometer needs to be designed to have a significant modulation effect on the incident light, and thus the matching of the refractive indexes of various structural layers appears to particularly important.

The present application can effectively make a small spectrum analysis device structure by employing the computational spectrum, and further provides a manufacturing process of a spectrum chip of the spectrum analysis device and a corresponding structure, so that the entire spectrum analysis device can be mass-produced.

### Example 1

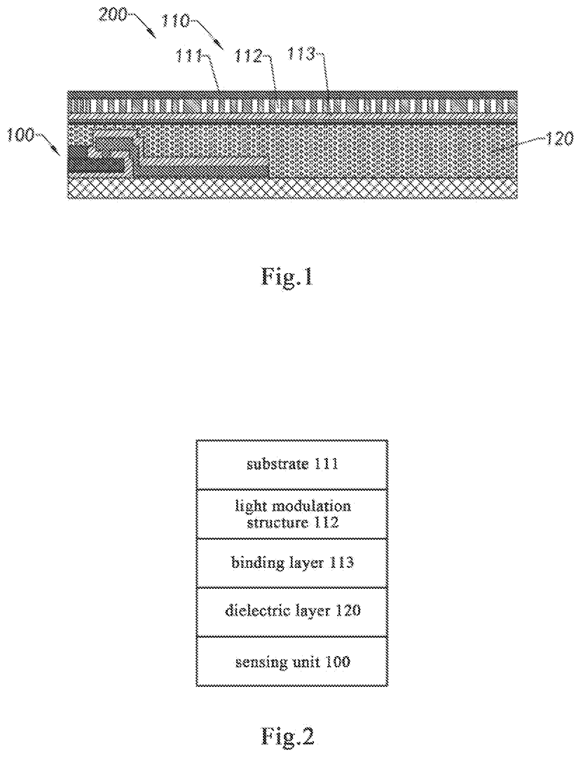

In example 1, as shown in FIG. 1 and FIG. 2, the spectrum chip 200 includes at least one sensing unit 100 and at least one modulation unit 110 held on a photosensitive path of the at least one sensing unit 100. The modulation unit 110 includes a substrate 111 and at least one light modulation structure 112 formed on the substrate 111. The light modulation structure 112 can modulate the light entering the spectrum chip 200 to generate a modulated light signal which is then received by the sensing unit 100.

In a specific implementation, in order to facilitate process implementation and ensure the performance of the spectrum chip 200, the substrate 111 is made of light-transmitting material, for example, transparent material, which specifically includes but is not limited to silicon dioxide, alumina, etc. In a specific implementation, the light modulation structure 112 may be formed on the substrate 111 by deposition or affixing or bonding (which also needs to cooperate with processes such as etching), wherein the material for making the light modulation structure 112 may be implemented as a high refractive index material such as silicon, silicon-based compound, titanium dioxide, tantalum oxide, aluminum oxide, aluminum nitride, or the like, or material with a large refractive index difference from the material of the substrate 111.

In a specific example of this example, the light modulation structure 112 and the substrate 111 have an integrated structure, which may be implemented by firstly forming a light modulation layer on the substrate 111 using processes such as deposition, affixing, bonding, etc., and then etching the light modulation layer using processes such as nano-imprinting, etching, etc. to form the light modulation structure 112 with at least one light modulation unit. Then, the integrated modulation unit 110 formed by the substrate 111 and the at least one light modulation structure 112 is fitted to the surface of the sensing unit 100, for example, the upper surface of the sensing unit 100, so that the modulation unit 110 is held on the photosensitive path of the sensing unit 100. In a specific implementation, the modulation unit 110 may be bound to the upper surface of the sensing unit 100 by processes such as bonding, adhesion, or affixing.

In this example, the sensing unit 100 includes at least one pixel unit 101, a logic circuit layer electrically connected to the pixel unit 101, and a memory electrically connected to the logic circuit layer. It is worth mentioning that, in some specific examples, the sensing unit 100 may also not include the memory, and only include the at least one pixel unit 101 and the logic circuit layer.

It should be noted that, as shown in FIG. 1 and FIG. 2, in this example, the modulation unit 110 may further include a binding layer 113 formed on a lower surface of the light modulation structure 112, wherein preferably, the binding layer 113 has a flat lower surface, so as to avoid the uneven lower surface of the light modulation structure 112 causing poor binding to the sensing unit 100 (for example, low matching accuracy) and thus affecting the performance of the spectrum chip 200.

In addition, the surface of the sensing unit 100 may be uneven, which will also affect the fitting effect, thereby affecting the performance of the spectrum chip 200. Accordingly, in this example, the spectrum chip 200 further includes a dielectric layer 120 formed on the surface of the sensing unit 100, for example, the dielectric layer 120 may be integrated on the surface of the sensing unit 10 by a process such as deposition and then the upper surface of the dielectric layer 120 is flattened. Then, the modulation unit 110 is transferred to the dielectric layer 120 in a manner that the binding layer 113 of the modulation unit 110 is bound to the dielectric layer 120, to obtain the spectrum chip 200, wherein the binding process for the transfer includes, but not limited to bonding, affixing, adhesion, etc. It is worth mentioning that the dielectric layer 120 may also be integrated onto the sensing unit 100, that is, the dielectric layer 120 is implemented as the upper surface of the sensing unit 100.

It is worth mentioning that, in this example, a distance a between the lower surface of the light modulation structure 112 and the upper surface of the dielectric layer 120 is limited, because when the distance is too large, it is easy to cause crosstalk of light, that is, the light modulated by the light modulation structure 112 has a certain divergence angle, and if the distance a is too large, the modulated light will enter the pixel unit 101 corresponding to the adjacent light modulation structure 112, thereby resulting in inaccurate information received by pixel unit 101 and further resulting in poor recovery accuracy. Further, preferably, the distance is less than or equal to twice the length of a side b of the light modulation structure 112, that is, a≤2b, wherein the light modulation structure 112 is composed of a plurality of micro-nano structures, each of which structure has a corresponding period, the shape and size of the modulation unit 110 may be defined according to the period of the micro-nano structure, such as being a square or a rectangle, and the distance is less than or equal to twice the length of the short side of the rectangle or twice the length of side of the square. In the case of high accuracy requirements, the distance a may be less than or equal to the length of side b, that is, a≤b. Further, too large distance a easily leads to the poor uniformity of the gap between the two. Preferably, the gap a is less than or equal to 10 um. It is understandable that some gaps larger than 10 um due to manufacturing errors are also within the scope of protection of the present application, that is, the distance between the lower surface of the light modulation structure 112 and the upper surface of the dielectric layer 120 is less than or equal to 10 um, however, it is not required that the gap corresponding to any one of the positions on the light modulation structure 112 and the dielectric layer 120 meets this requirement. It may be that some positions meet the requirement, but preferably it is ensured that at least 90% of the regions meet this requirement. More preferably, the distance between the lower surface of the light modulation structure 112 and the upper surface of the dielectric layer 120 is less than or equal to 5 um, for example, 2.5 um. Further, in order to ensure the performance of the spectrum chip 200, a difference in distances between any two regions in the lower surface of the light modulation structure 112 and the upper surface of the dielectric layer 120 is less than or equal to 10 um, preferably less than or equal to 5 um, thereby ensuring uniformity. It is also worth mentioning that, in this example, preferably, the binding layer 113 and the dielectric layer 120 have similar refractive index, and more preferably both are made of same material (for example, both are made of silicon dioxide). At the same time, the introduction of the binding layer 113 can also ensure the uniformity of the gap between the sensing unit 100 and the modulation unit 110, thereby helping to suppress interference fringes and their effects. In order to prevent particles greater than or equal to 2 microns from adhering to the surface, the sensing unit 100 and the modulation unit 110 are preferably cleaned, and then the sensing unit 100 is bound to the modulation unit 110.

Further, the problem of equal thickness interference is explained. Those of ordinary skill in the art should know that for a general image sensing device, the spectrum of the detected light usually covers a relatively large range (usually greater than 50 nm), for example, the visible light range or the near-infrared range. At this time, distribution positions of the equal thickness fringes are different due to the different wavelength, after being superimposed on each other, the brightness and darkness will cancel. Therefore, the problem of equal thickness interference is not obvious in general image sensing devices. However, for a spectrometer device which needs to have a high spectral resolution and detect the monochromatic light, if the thickness of a certain structural layer is not uniform, significant equal thickness interference fringes will appear. That is, for computational spectrometers or spectrum imaging devices, it will further affect the detection accuracy. Further, for the visible light field, the wavelength is in the order of hundreds of nanometers, and thus a small amount of mismatch or non-uniformity will cause a large error. Accordingly, the spectrum chip 200 proposed in the present application can effectively control the optical path consistency of the overall structure, so as to eliminate the influence caused by the equal thickness interference.

It should also be noted that at least one pixel unit 101 of the sensing unit 100 corresponds to at least one light modulation unit of the light modulation structure 112 to form a modulation unit pixel, and a plurality of modulation unit pixels constitute a spectrum pixel. On the basis of disregarding the reconfigurable spectrum pixels (re-selecting modulation unit pixels to construct spectrum pixels by using an algorithm based on demand), if there are two modulation unit pixels in one of the spectrum pixels, the light modulation units contained in the two modulation unit pixels are usually different, and in principle, it can be understood that the structures of the light modulation units corresponding to the adjacent modulation unit pixels are different.

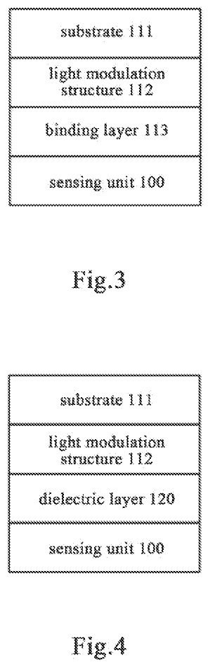

FIG. 3 illustrates a block diagram of a variant implementation of the spectrum chip 200 according to an example of the present application. As shown in FIG. 3, in this variant example, the dielectric layer 120 is not provided on the surface of the sensing unit 100, but the modulation unit 110 is directly bound to the sensing unit 100, or it can be understood that the dielectric layer 120 is the upper surface of the sensing unit 100. FIG. 4 illustrates a block diagram of another variant implementation of the spectrum chip 200 according to an example of the present application. In this variant example, the binding layer 113 is not provided on the lower surface of the light modulation structure 112, but the modulation unit 110 is directly bound to the sensing unit 100.

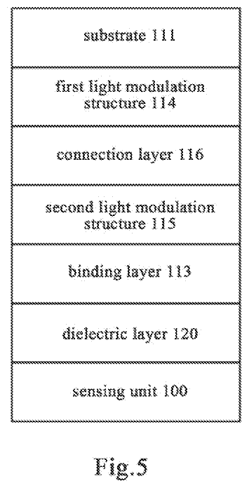

FIG. 5 illustrates a block diagram of yet another variant implementation of the spectrum chip 200 according to an example of the present application. As shown in FIG. 5, in this variant example, the modulation unit 110 includes two or more layers of light modulation structures 112, so as to make the transmission spectrum more complex by the cooperation of at least two layers of the light modulation structures 112, that is, two or more layers of light modulation structures 112 may be obtained by the combination of the simple light modulation structures 112 to form a complex transmission spectrum, thereby reducing the requirement on the processing accuracy of the light modulation structures 112. Preferably, there are at least two layers of the light modulation structures 112 and the two layers of the light modulation structures 112 are different, that is, the corresponding regions of the two light modulation layers have different modulation effects on the same incident light.

For example, in the example illustrated in FIG. 5, the modulation unit 110 includes two layers of light modulation structures 112: a first light modulation structure 114 and a second light modulation structure 115. In particular, in this variant example, the light modulation unit of the first light modulation structure 114 and/or the light modulation unit of the second light modulation structure 115 have fillers.

As shown in FIG. 5, in this example, a connection layer 116 may also be provided between the first light modulation structure 114 and the second light modulation structure 115. Preferably, the connection layer 116 is made of material with low refractive index (the reason is that the first light modulation structure 114 and the second light modulation structure 115 are made of material with high refractive index). Correspondingly, the substrate 111, the first light modulation structure 114, the connection layer 116, the second light modulation structure 115, the binding layer 113 and the dielectric layer 120 interact and jointly modulate the incident light to generate a modulation signal.

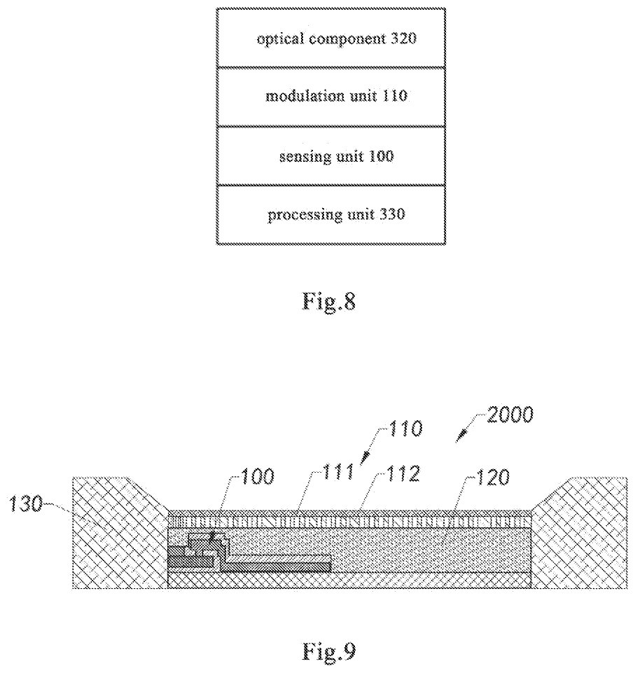

Further, as shown in FIG. 8, the present application provides a spectrum analysis device, such as a spectrometer and a spectrum imaging device. The spectrum analysis device includes the spectrum chip 200 and a circuit board 310, and the spectrum chip 200 is conductively connected to the circuit board 310, thereby realizing signal transmission and so on. Further, optionally, the spectrum analysis device may further include an optical component 320, such as a lens component, etc., which is located on the light-passing path of the spectrum chip 200. After passing through the optical component 320, the incident light enters the light modulation layer of the spectrum chip 200 to be modulated, and then is received by the sensing unit 100 and converted into an electrical signal. The spectrum analysis device further includes an encapsulation body (e.g., a plastic bracket, a metal bracket), and the spectrum chip 200 is accommodated in the encapsulation body. Further, in some examples of the present application, the spectrum analysis device may further include a processing unit 330 for processing the electrical signal to generate a spectrum or an image or the like.

According to another aspect of the present application, a method for manufacturing the spectrum chip 200 is also provided, which is used for manufacturing the spectrum chip 200 as described above. As mentioned above, in order to achieve mass production, the current spectrum chip 200 is manufactured by the following manufacturing process: firstly, a layer of a light modulation layer material is deposited on an existing image sensor (e.g., CMOS image sensor, CCD sensor); then, the light modulation layer material is etched to form the light modulation layer, that is, the light modulation structure 112 is obtained by processing the light modulation layer. However, this manufacturing process has many problems in practical industrial implementation.

Specifically, the manufacturing process of the spectrum chip 200 needs processing on the wafer of chip, and thus it is necessary to provide product lines and production teams that match the wafer-level processing, which will lead to an increase in costs on the one hand, and is difficult to be implemented in industry due to the monopoly of the wafer processing technology on the other hand. In addition, the process of depositing the light modulation layer structure according to the characteristics of the material needs to be carried out under certain high temperature conditions, however, the high temperature may cause damage to the wafer. Conversely, considering the heat resistance of the wafer, compromises must be made in the selection of the light modulation layer material, which will result in the light modulation layer not reaching the optimum performance due to the selection of the material. In addition, since the image sensor contains a logic circuit, metal powders may be generated to pollute the manufacturing environment.

In view of the above technical difficulties, the inventors of the present application tried to transfer the process of forming the light modulation structure 112 to be performed on the substrate 111, so as to get rid of the limitation of the existing manufacturing process of the spectrum chip 200 limited by the fab on the one hand, and on the other hand to ensure that the spectrum chip 200 will not be polluted during the manufacturing process. That is, the modulation unit 110 of the spectrum chip 200 is separately formed on the substrate 111 and then coupled to the sensor. In this way, the problem that the current manufacturing process of the spectrum chip 200 is limited by the fab is solved. Moreover, since the modulation unit 110 does not include a logic circuit, no contamination of metal powders and the like occur during the manufacturing process and further it can be ensured that no contamination occurs during processing process. At the same time, it can avoid high temperature affecting the performance of the sensor.

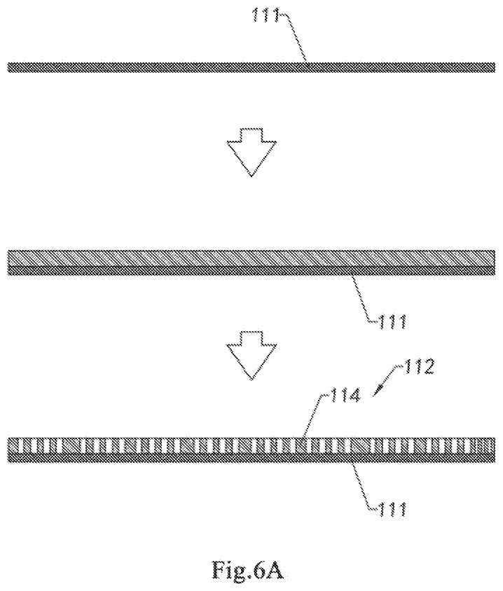

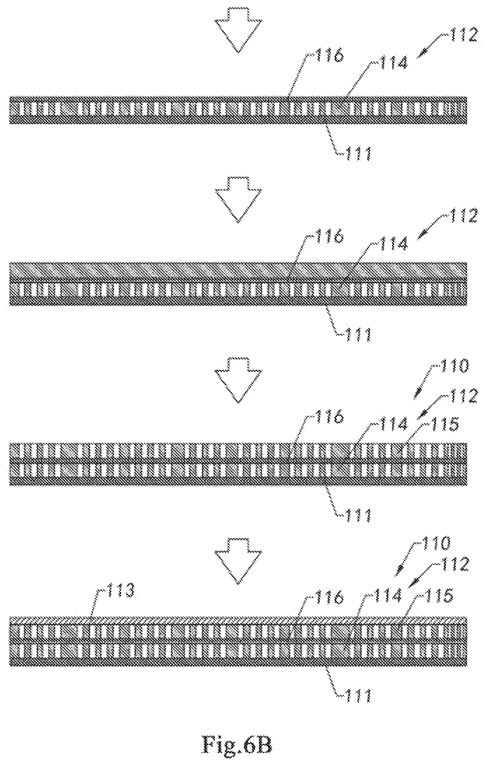

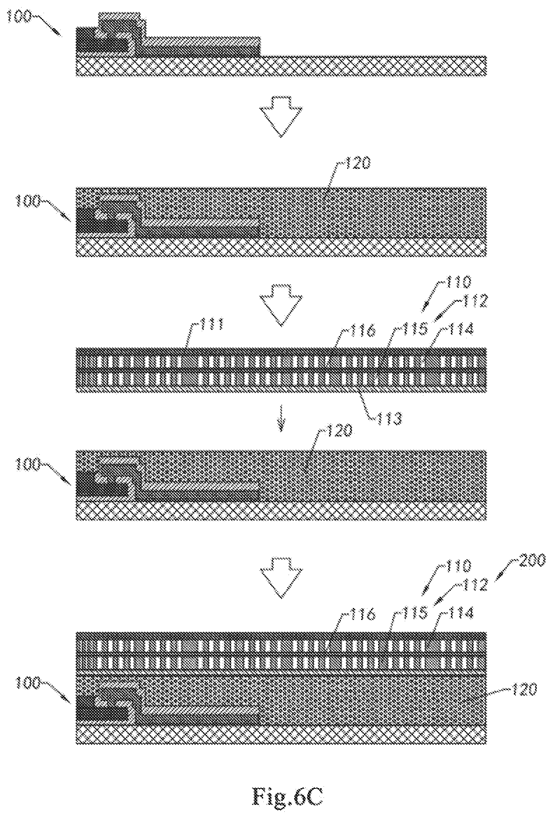

FIGS. 6A to 6C are schematic diagrams illustrating a method for manufacturing the spectrum chip 200 according to an example of the present application. As shown in FIGS. 6A to 6C, the manufacturing process of the spectrum chip 200 according to the example of the present application includes: firstly providing the substrate 111, wherein the substrate 111 is made of material selected from silicon dioxide or alumina or other transparent materials, such as quartz, sapphire, etc., or transparent organic materials, such as plastic, acrylic, etc., or metal materials, such as germanium.

Then, at least one light modulation structure 112 is formed on the substrate 111 to obtain the modulation unit 110. Correspondingly, when the at least one modulation unit 110 includes only one layer of the light modulation structure 112, for example, includes only the first light modulation structure 114, the process of forming at least one light modulation structure on the substrate 111 to obtain the modulation unit 110 includes: firstly forming a first light modulation layer on the substrate 111, for example, forming the first light modulation layer on the substrate 111 by a deposition process which may be chemical vapor deposition (CVD), atomic layer deposition (ALD), plasma enhanced chemical vapor deposition (PECVD), physical vapor deposition (PVD), etc.; and then etching the first light modulation layer to form the first light modulation structure 114 with at least one first modulation unit 110, for example, etching the first light modulation layer by nano-imprinting, etching and other processes to form the first light modulation structure 114 with at least one first modulation unit 110.

Of course, the first light modulation layer may also be formed on the substrate 111 by other processes, for example, firstly the first light modulation layer is prefabricated, and then is stacked on the substrate 111 by an attaching process.

Correspondingly, when the at least one light modulation structure 112 includes at least two layers of light modulation structures 112, for example, includes the first light modulation structure 114 and the second light modulation structure 115, the process of forming at least one light modulation structure on the substrate 111 to obtain the modulation unit 110 includes: firstly forming a first light modulation layer on the substrate 111, for example, forming the first light modulation layer on the substrate 111 by a deposition process, then etching the first light modulation layer to form the first light modulation structure 114 with at least one first modulation unit 110, for example, etching the first light modulation layer by nano-imprinting, etching and other processes to form the first light modulation structure 114 with at least one first modulation unit 110; then forming a second light modulation layer on the first light modulation structure 114, for example, forming the second light modulation layer on the first light modulation structure 114 by a deposition process, and then etching the second light modulation layer to form the second light modulation structure 115 with at least one second modulation unit 110. Preferably, before the second light modulation layer is deposited, the first light modulation structure 114 is filled, that is, the first light modulation structure 114 has filler.

Further, in some examples, the modulation unit 110 may be directly formed by processing an SOI substrate 111 (Silicon-On-Insulator substrate 111) or an SOS substrate 111 (silicon on sapphire substrate 111). Taking the SOS substrate 111 as an example, the SOS substrate 111 is generally composed of sapphire and a silicon single crystal, and a light modulation structure 112 with at least one modulation unit 110 is formed by processing the silicon single crystal.

It is worth mentioning that in some examples of the present application, a connection layer 116 may also be provided on the first light modulation structure 114. Preferably, the connection layer 116 is made of a material with low refractive index, so as to bind the first light modulation structure 114 to the second light modulation structure 115 by the connection layer 116. Correspondingly, in this example, forming the second light modulation layer on the first light modulation structure 114 includes: firstly, forming a connection layer 116 on the first light modulation layer; and then, forming the second light modulation layer on the connection layer 116.

Then, a sensing unit 100 is provided. The sensing unit 100 includes at least one pixel unit 101, a logic circuit layer electrically connected to the pixel unit 101, and a memory electrically connected to the logic circuit layer. It is worth mentioning that, in some specific examples, the sensing unit 100 may also not include the memory, but only include the at least one pixel unit 101 and the logic circuit layer.

Next, the modulation unit 110 is coupled to the sensing unit 100, so that the modulation unit 110 is held on the photosensitive path of the sensing unit 100 to obtain the spectrum chip 200. In this example, the modulation unit 110 is coupled to the sensing unit 100 in a flip-chip manner, wherein at least one light modulation structure 112 of the modulation unit 110 is stacked on the sensing unit 100. In a specific example, the process of coupling the modulation unit 110 to the sensing unit 100 in the flip-chip manner includes: firstly, forming a dielectric layer 120 on the sensing unit 100, wherein preferably, the dielectric layer 120 is made of material with low refractive index; and then coupling the modulation unit 110 to the dielectric layer 120. Optionally, before coupling, the modulation unit 110 and/or the sensing unit 100 may be cleaned to remove surface particles.

In order to prevent the uneven lower surface of the light modulation structure 112 from causing poor binding to the sensing unit 100 (for example, low matching accuracy) and thus affecting the performance of the spectrum chip 200, in some examples of the present application, a binding layer 113 may also be formed on at least one light modulation structure 112 of the modulation unit 110; and then, the modulation unit 110 is coupled to the dielectric layer 120 in a manner that the binding layer 113 is bound to the dielectric layer 120. Preferably, the binding layer 113 and the dielectric layer 120 have the similar refractive index, and more preferably both are made of the same material (for example, both are made of silicon dioxide).

It is worth mentioning that, in this example, a distance a between the lower surface of the light modulation structure 112 and the upper surface of the dielectric layer 120 is limited, because when the distance is too large, it is easy to cause crosstalk of light, that is, the light modulated by the light modulation structure 112 has a certain divergence angle, and if the distance a is too large, the modulated light will enter the pixel unit 101 corresponding to the adjacent light modulation structure 112, thereby resulting in inaccurate information received by pixel unit 101 and further poor recovery accuracy. Further, preferably, the distance is less than or equal to twice the length of a side b of the light modulation structure 112, that is, a≤2b, wherein the light modulation structure 112 is composed of a plurality of micro-nano structures, and each micro-nano structure has a corresponding period, the shape and size of the modulation unit 110 may be defined according to the period of the micro-nano structure, such as being a square or a rectangle, and the distance is less than or equal to twice the length of the short side of the rectangle or twice the length of side of the square. In the case of high accuracy requirements, the distance a may be less than or equal to the length of side b, that is, a≤b. Further, too large distance a easily leads to the poor uniformity of the gap between the two. Preferably, the gap a is less than or equal to 10 um. It is understandable that some gaps larger than 10 um due to manufacturing errors are also within the scope of protection of the present application, that is, the distance between the lower surface of the light modulation structure 112 and the upper surface of the dielectric layer 120 is less than or equal to 10 um, however, it is not required that the gap corresponding to anyone of the positions on the light modulation structure 112 and the dielectric layer 120 meets this requirement. It may be that some positions meet the requirement, but preferably it is ensured that at least 90% of the regions meet this requirement. More preferably, the distance between the lower surface of the light modulation structure 112 and the upper surface of the dielectric layer 120 is less than or equal to 5 um, for example, 2.5 um. Further, in order to ensure the performance of the spectrum chip 200, the difference in distances between any two regions in the lower surface of the light modulation structure 112 and the upper surface of the dielectric layer 120 is less than or equal to 20 um, preferably less than or equal to 10 um or 5 um, thereby ensuring uniformity. It is also worth mentioning that, in this example, preferably, the binding layer 113 and the dielectric layer 120 have the similar refractive index, and more preferably both are made of the same material (for example, both are made of silicon dioxide). At the same time, the introduction of the binding layer 113 can also ensure the uniformity of the gap between the sensing unit 100 and the modulation unit 110, thereby helping to suppress interference fringes and their effects.

In order to enable mass production, a jointed panel process may be implemented for the sensing units 100, that is, a sensing unit jointed panel 1000 has at least two sensing units 100, wherein the sensing unit 100 may be a CMOS, CCD, or indium gallium arsenide sensor, and a modulation sensor with a filter structure such as quantum dots or nanowires on the upper surface; and then a dielectric layer 120 is formed on the surfaces of the sensing units 100 by a process such as deposition, and the upper surface of the dielectric layer 120 is flattened. Correspondingly, at least two light modulation structures 112 are formed on the substrate 111 to form a modulation unit jointed panel 1100, and then the modulation unit jointed panel 1100 is applied to the flat dielectric layer 120 on the sensing unit jointed panel to obtain a semi-finished spectrum chip 2000, wherein the light modulation structures 112 of the modulation units 110 are aligned with the corresponding sensing units 100, and then the semi-finished spectrum chip 2000 is cut to obtain the spectrum chips 200.

Here, the substrate 111 may be implemented as quartz, sapphire, etc. The light modulation layer material may be deposited on the surface of the substrate 111, and then the light modulation structure 112 is formed by nano-imprinting, etching, etc. The modulation unit jointed panel 1100 may be understood as a plurality of identical modulation units 110 formed on a substrate 111, and each modulation unit 110 and the corresponding sensing unit 100 constitute a modulation unit pixel.

That is, in this example of the present application, the method for manufacturing the spectrum chip 200 includes steps of: firstly, providing the substrate 111; next, forming an array of light modulation structures 112 on the substrate 111 to obtain the modulation unit jointed panel 1100, wherein the array of the light modulation structures includes at least two light modulation structures 112; then, providing the sensing unit jointed panel 1000 which includes at least two sensing units 100; then, coupling the modulation unit jointed panel 1100 to the sensing unit jointed panel 1000 to obtain the jointed panel of the spectrum chip 200, wherein optionally, before the coupling, the modulation unit jointed panel 1100 and/or the sensing unit jointed panel are cleaned to remove surface particles; finally, dividing the jointed panel of the spectrum chip 200 to obtain at least two spectrum chips 200.

### Example 2

The difference from example 1 is that the sensing unit 100 and the modulation unit 110 are only implemented to be simply fitted together, with van der Waals forces formed between them. Preferably, after the spectrum chip 200 is formed and affixed to the circuit board 310, an encapsulation body 130 is formed on the surface of the circuit board 310 and the side and/or surface of the spectrum chip 200. The circuit board 310, the spectrum chip 200 and the encapsulation body 130 are in an integrated structure by the encapsulation body 130, as shown in FIG. 9. In individual examples, the encapsulation body 130 does not need to be matched with the circuit board, that is, the encapsulation body 130 is fitted with the sensing unit 100 and the modulation unit 110, so that the sensing unit 100 and the modulation unit 110 are fixed by the encapsulation body 130.

Further, the encapsulation body 130 serves to fix the sensing unit 100 and the modulation unit 110 of the spectrum chip 200 in this example. In this example, the sensing unit 100 and the modulation unit 110 are directly fitted, and the fixing of the modulation unit 110 and the sensing unit 100 is realized by the encapsulation body 130. That is, in this example, the sensing unit 100 and the modulation unit 110 do not need to be bonded or adhered by an adhesive, so that it is ensured that the gap between the two is less than or equal to 2.5 μm, and at the same time, the refractive index change caused by the adhesive, the excess temperature possibly caused by the bonding and other problems can be avoided to a certain extent. It is worth mentioning that the encapsulation body 130 is equivalent to a bracket in the spectrum analysis device, and may be used to support the optical module 320 and the like.

Further, the encapsulation body 130 may be formed by a molding process. That is, the jointed panel of the circuit board 310 and the spectrum chip 200 are assembled and electrical conduction is achieved, and then it is placed in a mold, and then a molding material is injected. The mold is opened after curing, and the spectrum chip 200 is obtained by cutting. It is also possible to set a mold on the spectrum chip 200 and the circuit board 310, and then inject the adhesive into the mold. The encapsulation body 130 is formed after the adhesive is cured.

Of course, it is also possible to directly fix the spectrum chip 200 by the encapsulation body 130 obtained by processing using gluing and the like. It is worth mentioning that in this example, how the encapsulation body 130 is disposed and formed is not limited, and it only needs to realize that the spectrum chip 200, the circuit board 310 and the encapsulation body 130 can be formed into one piece by the encapsulation body 130, to improve the reliability of the spectrum analysis device. Further, the encapsulation body 130 can play the role of fixing the sensing unit 100 and the modulation unit 110.

Further, in this example, the encapsulation body 130 includes a main body and a fixing part integrally extending inward from the main body, and the adhesive is provided on the fixing part and the bottom of the main body of the encapsulation body 130, so that the fixing part is adhered to the upper surface of the substrate 111 of the modulation unit 110, and the bottom of the main body is adhered to the circuit board 310 by the adhesive. Therefore, the spectrum chip 200, the circuit board 310 and the encapsulation body 130 are formed into one piece by the encapsulation body 130.

It is worth mentioning that, preferably, the side wall of the main body clings to the side wall of the spectrum chip 200, so as to prevent horizontal sliding. Preferably, the encapsulation body 130 is made of an opaque material, so that the encapsulation body 130 can also prevent stray light from entering the spectrum chip 200 from the side of the modulation unit 110, thereby reducing the accuracy.

### Example 3

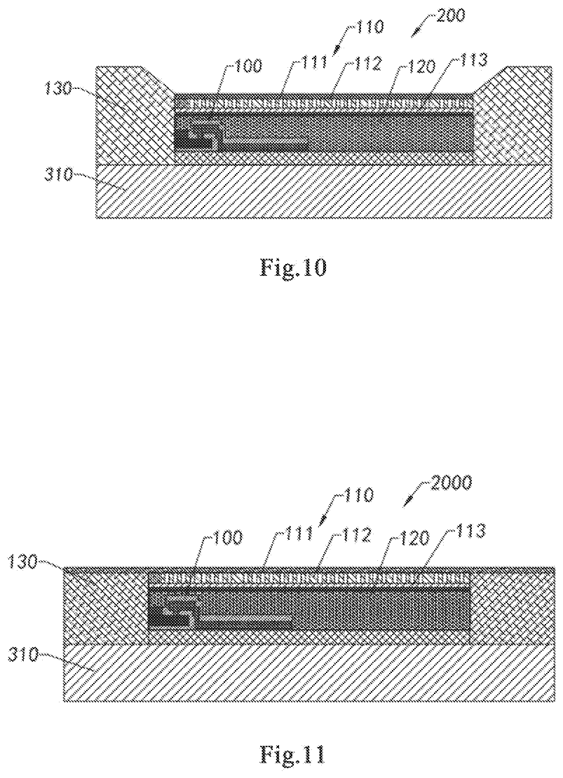

As shown in FIG. 10, the present application also provides a photosensitive component, which includes a circuit board 310 and a spectrum chip 200 electrically connected to the circuit. The photosensitive component includes an encapsulation body 130 which is formed on the surface of the circuit board 310 and surrounds the sensing unit 100 of the spectrum chip 200.

Preferably, the photosensitive component is obtained by the following. Firstly, the sensing unit 100 of the spectrum chip 200 is affixed to the circuit board 310 and electrical conduction is achieved (COB and CSP are both acceptable), preferably there is a dielectric layer 120 with a flat upper surface on the surface of the sensing unit 100. Then the encapsulation body 130 is formed on the non-photosensitive region of the sensing unit 100 and the surface of the circuit board 310 by processes such as molding and affixing, that is, it can be understood that the sensing unit 100, the circuit board 310 and the encapsulation body 130 are in an integrated structure. Then the modulation unit 110 is affixed to the surface of the sensing unit 100 to obtain the photosensitive module. Further, a distance between the lower surface of the light modulation structure 112 of the modulation unit 110 and the upper surface of the dielectric layer 120 of the sensing unit 100 is less than or equal to 2.5 μm. Preferably, the modulation unit 110 and the encapsulation body 130 are fixed by an adhesive. It is worth mentioning that the thickness of the adhesive is less than or equal to 2.5 μm, and preferably, the refractive index of the adhesive may be the same as that of the dielectric layer 120 or the light modulation layer, so as to prevent the generation of equal thickness interference.

Preferably, a jointed panel process may also be performed in this example. That is, a jointed panel of the circuit board 310 is provided, and the sensing units 100 are respectively affixed to the circuit boards 310, preferably, there is a dielectric layer 120 with a flat upper surface on the surfaces of the sensing units 100. Then an encapsulation body 130 is formed on the circuit boards 310 and the non-photosensitive regions of the sensing units 100 by molding, pasting, etc. . . . Then the modulation unit jointed panel 1100 is affixed to the jointed panel of the circuit board 310, and the modulation units 110 are aligned with the sensing units 100 to form a plurality of pixels of the modulation unit 110. Optionally, the modulation unit 110 and the sensing unit 100 may be cleaned to remove surface particles before they are bound. It is worth mentioning that the surface of the encapsulation body 130 is generally flat, and an adhesive may be coated on the surface of the encapsulation body 130. Since there is a certain distance between modulation units 110 of the modulation unit jointed panel 1100, that is, there is an affixing region between the modulation units 110, the affixing region of the modulation unit jointed panel 1100 is adhered to the encapsulation body 130 by the adhesive on the encapsulation body 130 after the modulation unit jointed panel 1100 is affixed to the jointed panel of the circuit board 310, so that the jointed panel of the circuit board 310 and the modulation unit jointed panel 1100 are fixed to obtain the photosensitive component jointed panel which is then is cut to obtain photosensitive component.

Optionally, the photosensitive component further includes a light shielding member, which is formed on the side and the surface edge of the substrate 111 to prevent stray light from entering the sensing unit 100.

### Example 4

The difference from the example 3 is that, as shown in FIG. 11, in this example, the encapsulation body 130 does not wrap the sensing unit 100. That is, the encapsulation body 130 having a light-passing port (also provided in all of the previous examples) is firstly formed on the circuit board 310, and then the sensing unit 100 is affixed to the circuit board 310 through the light-passing port and the conduction is realized. Then the modulation unit jointed panel 1100 is affixed to the jointed panel of the circuit board 310, and the upper surface of the encapsulation body 130 is provided with an adhesive for adhering the affixing region of the modulation unit jointed panel 1100. Then, the photosensitive component jointed panel is cut to obtain the photosensitive components. At this time, an adhesive may be applied between the modulation unit 110 and the sensing unit 100.

For the examples 3 and 4, the modulation unit 110 may also be individually affixed to the surface of each sensing unit 100. In addition, it should be noted that the distance between the upper surface of the dielectric layer 120 of the modulation unit 110 and the lower surface of the light modulation structure 112 of the modulation unit 110 is less than or equal to 2.5 μm. Therefore, when designing, the height c of the light modulation structure 112 needs to be set according to the distance a between the upper surface of the encapsulation body 130 and the upper surface of the dielectric layer 120, as well as the thickness b of the adhesive disposed on the upper surface of the encapsulation body 130, that is, a+b−c≤2 μm.

### Example 5

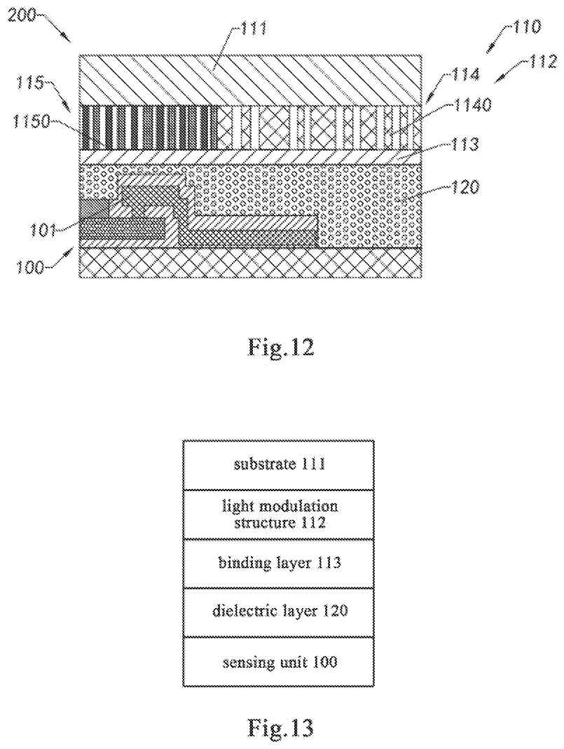

In the example 5, as shown in FIG. 12 and FIG. 13, the spectrum chip 200 includes at least one sensing unit 100 and at least one modulation unit 110 held on the photosensitive path of the at least one sensing unit 100. The modulation unit 110 includes a substrate 111 and at least one light modulation structure 112 formed on the substrate 111. The light modulation structure 112 can modulate the light entering the spectrum chip 200 to generate a modulated light signal which is then received by the sensing unit 100.

As shown in FIG. 12, the light modulation structure 112 includes a modulation portion 114 and a non-modulation portion 115, wherein the modulation portion 114 includes at least one light modulation unit 1140, and the light modulation unit 1140 may be a modulation hole, a modulation column, a modulation line, etc., and is used to modulate the signal of the incident light entering the sensing unit 100 to generate a modulated signal; the non-modulation portion 115 includes at least one filter unit 1150, which is used to filter the signal of the incident light entering the sensing unit 100.

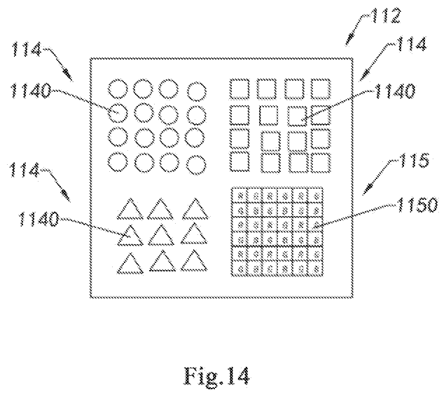

In this example of the present application, the filter unit 1150 may be a filter unit 1150 such as R, G, B, W, Y. For example, the filter unit 1150 may constitute an RGGB, RYYB, RGBW Bayer filter, or a single filter unit or a combination of multiple filter units constitute an irregular Bayer filter, as shown in FIG. 14. Of course, in other examples of the present application, the non-modulation portion 115 may also be a portion that does not include any optical modulation function and is only composed of a light-transmitting material, or may be a portion without any material.

In a specific implementation, in order to facilitate process implementation and ensure the performance of the spectrum chip 200, the substrate 111 is made of a light-transmitting material, for example, a transparent material, which specifically includes but is not limited to silicon dioxide, alumina, etc., such as quartz, sapphire, etc. In a specific implementation, the light modulation structure 112 may be formed on the substrate 111 by deposition or affixing or bonding (of course, which also needs to cooperate with processes such as etching), wherein the material of the light modulation structure 112 may be implemented as a high refractive index material such as silicon, silicon-based compound, titanium dioxide, tantalum oxide, aluminum oxide, aluminum nitride, or the like, or a material with a large refractive index difference from the material of the substrate 111.

That is, in the example of the present application, the light modulation structure 112 and the substrate 111 have an integrated structure. In the specific manufacturing process, a light modulation layer may be formed on the substrate 111 by processes such as deposition, affixing, bonding, etc., and then the light modulation layer is etched by processes such as nano-imprinting, etching, etc. to form the light modulation structure 112 having the modulating portion 114 and the non-modulating portion 115. Then, the integrated modulation unit 110 formed by the substrate 111 and the at least one light modulation structure 112 is fitted to the surface of the sensing unit 100, for example, the upper surface of the sensing unit 100, so that the modulation unit 110 is held on the photosensitive path of the sensing unit 100. In a specific implementation, the modulation unit 110 may be bound to the upper surface of the sensing unit 100 by processes such as bonding, adhesion, or affixing.

In this example, the sensing unit 100 includes at least one pixel unit 101, a logic circuit layer electrically connected to the pixel unit 101, and a memory electrically connected to the logic circuit layer. It is worth mentioning that, in some specific examples, the sensing unit 100 may also not include the memory, but only include the at least one pixel unit 101 and the logic circuit layer.

It should be noted that, as shown in FIG. 12 and FIG. 13, the modulation unit 110 may further include a binding layer 113 formed on the lower surface of the light modulation structure 112, wherein preferably, the binding layer 113 has a flat lower surface, so as to avoid the uneven lower surface of the light modulation structure 112 causing poor binding to the sensing unit 100 (for example, low matching accuracy) and thus affecting the performance of the spectrum chip 200.

In addition, the surface of the sensing unit 100 may be uneven, which will also affect the fitting effect, thereby affecting the performance of the spectrum chip 200. Accordingly, in this example, the spectrum chip 200 further includes a dielectric layer 120 formed on the surface of the sensing unit 100, for example, the dielectric layer 120 may be integrated onto the surface of the sensing unit 10 by a process such as deposition and then the upper surface of the dielectric layer 120 is flattened. Then, the modulation unit 110 is transferred to the dielectric layer 120 in a manner that the binding layer 113 of the modulation unit 110 is bound to the dielectric layer 120, to obtain the spectrum chip 200, wherein the binding process for the transfer includes, but not limited to bonding, affixing, adhesion, etc. It is worth mentioning that the dielectric layer 120 may also be integrated into the sensing unit 100, that is, the dielectric layer 120 is implemented as the upper surface of the sensing unit 100.

It is worth mentioning that, in this example, a distance a between the lower surface of the light modulation structure 112 and the upper surface of the dielectric layer 120 is limited, because when the distance is too large, it is easy to cause crosstalk of light, that is, the light modulated by the light modulation structure 112 has a certain divergence angle, and if the distance a is too large, the modulated light will enter the pixel unit 101 corresponding to the adjacent light modulation structure 112, thereby resulting in inaccurate information received by pixel unit 101 and further poor recovery accuracy. Further, preferably, the distance is less than or equal to twice the length of a side b of the light modulation structure 112, that is, a≤2b, wherein the light modulation structure 112 is composed of a plurality of light modulation units 1140, each of which has a corresponding period, the shape and size of the modulation unit 110 may be defined according to the period of the light modulation unit 1140, such as being a square or a rectangle, and the distance is less than or equal to twice the length of the short side of the rectangle or twice the length of side of the square. In the case of high accuracy requirements, the distance a may be less than or equal to the length of side b, that is, a≤b. Further, too large distance a easily leads to the poor uniformity of the gap between the two. Preferably, the gap a is less than or equal to 10 um. It is understandable that some gaps larger than 10 um due to manufacturing errors are also within the scope of protection of the present application, that is, the distance between the lower surface of the light modulation structure 112 and the upper surface of the dielectric layer 120 is less than or equal to 10 um, however, it is not required that the gap corresponding to anyone of the positions on the light modulation structure 112 and the dielectric layer 120 meets this requirement. It may be that some positions meet the requirement, but preferably it is ensured that at least 90% of the regions meet this requirement. More preferably, the distance between the lower surface of the light modulation structure 112 and the upper surface of the dielectric layer 120 is less than or equal to 5 um, for example, 2.5 um. Further, in order to ensure the performance of the spectrum chip 200, the difference in distances between any two regions in the lower surface of the light modulation structure 112 and the upper surface of the dielectric layer 120 is less than or equal to 10 um, preferably less than or equal to 5 um, thereby ensuring uniformity. It is also worth mentioning that, in this example, preferably, the binding layer 113 and the dielectric layer 120 have the similar refractive index, and more preferably both are made of the same material (for example, both are made of silicon dioxide). At the same time, the introduction of the binding layer 113 can also ensure the uniformity of the gap between the sensing unit 100 and the modulation unit 110, thereby helping to suppress interference fringes and their effects. In order to prevent particles greater than or equal to 2 microns from adhering to the surface, the sensing unit 100 and the modulation unit 110 are preferably cleaned, and then the sensing unit 100 is bound to the modulation unit 110.

Further, the problem of equal thickness interference is explained. Those of ordinary skill in the art should know that for a general image sensing device, the spectrum of the detected light usually covers a relatively large range (usually greater than 50 nm), for example, the visible light range or the near-infrared range. At this time, distribution positions of the equal thickness fringes are different due to the different wavelength, after being overlaid on each other, the brightness and darkness will cancel. Therefore, the problem of equal thickness interference is not obvious in general image sensing devices. However, for a spectrometer device which needs to have a high spectral resolution and detect the monochromatic light, if the thickness of a certain structural layer is not uniform, significant equal thickness interference fringes will appear. That is, for computational spectrometers, it will further affect the detection accuracy. Further, for the visible light field, the wavelength is in the order of hundreds of nanometers, and thus a small amount of mismatch or non-uniformity will cause a large error. Accordingly, the spectrum chip 200 proposed in the present application can effectively control the optical path consistency of the overall structure, so as to eliminate the influence caused by the equal thickness interference.

It should also be noted that at least one pixel unit 101 of the sensing unit 100 corresponds to at least one light modulation unit of the light modulation structure 112 to form a modulation unit pixel, and a plurality of modulation unit pixels constitute a spectrum pixel. On the basis of disregarding the reconfigurable spectrum pixels (re-selecting modulation unit pixels to construct spectrum pixels by using an algorithm based on demand), if there are two modulation unit pixels in one of the spectrum pixels, the light modulation units contained in the two modulation unit pixels are usually different, and in principle, it can be understood that the structures of the light modulation units corresponding to the adjacent modulation unit pixels are different.

It is worth mentioning that in other examples of the present application, the dielectric layer 120 may be not provided on the surface of the sensing unit 100, but the modulation unit 110 is directly bound to the sensing unit 100, or it can be understood that the dielectric layer 120 is the upper surface of the sensing unit 100. Of course, the binding layer 113 may also be not provided on the lower surface of the light modulation structure 112, but the modulation unit 110 is directly bound to the sensing unit 100.

Furthermore, in other variant examples of the present application, the modulation unit 110 may include a greater number of light modulation structures 112, that is, the modulation unit 110 includes two or more layers of light modulation structures 112, so as to make the transmission spectrum more complex by the cooperation of the light modulation structures 112, that is, two or more layers of light modulation structures 112 may be obtained by the combination of the simple light modulation structures 112 to form a complex transmission spectrum, thereby reducing the requirement on the processing accuracy of the light modulation structures 112. Preferably, there are at least two layers of the light modulation structures 112 and the two layers of the light modulation units 1140 are different, that is, the corresponding regions of the two light modulation layers have different modulation effects on the same incident light.

For example, in a specific variant example, the at least one light modulation structure 112 includes two layers of light modulation structures 112: a first light modulation structure and a second light modulation structure. Preferably, the light modulation unit 1140 of the first light modulation structure and/or the light modulation unit 1140 of the second light modulation structure have fillers. Further, a connection layer may also be provided between the first light modulation structure and the second light modulation structure, preferably, the connection layer is made of material with low refractive index (the reason is that the first light modulation structure 114 and the second light modulation structure 115 are made of material with high refractive index). In addition, a protective layer may also be provided on the upper surface of the first light modulation structure (in this example, the substrate 111 forms the protective layer). Correspondingly, the substrate 111, the first light modulation structure, the connection layer, the second light modulation structure, the binding layer 113 and the dielectric layer 120 interact and jointly modulate the incident light to generate a modulation signal.

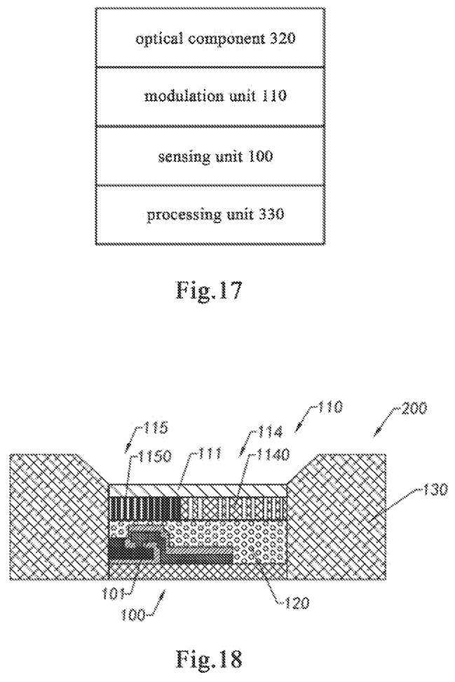

Further, as shown in FIG. 17, the present application also provides a spectrum analysis device 300, such as a spectrometer and a spectrum imaging device. The spectrum analysis device 300 includes the spectrum chip 200 and a circuit board, and the spectrum chip 200 is conductively connected to the circuit board to realize signal transmission and so on. Further, optionally, the spectrum analysis device 300 may further include an optical component 320, such as a lens component, etc., which is located on the light-passing path of the spectrum chip 200. After passing through the optical component 320, the incident light enters the light modulation layer of the spectrum chip 200 to be modulated, and then is received by the sensing unit 100 and converted into an electrical signal. The spectrum analysis device 300 further includes an encapsulation body (eg, a plastic bracket, a metal bracket), and the spectrum chip 200 is accommodated in the encapsulation body. Further, in some examples of the present application, the spectrum analysis device 300 may further include a processing unit 330 for processing the electrical signal to generate a spectrum or an image or the like.

According to another aspect of the present application, a method for manufacturing the spectrum chip 200 is also provided, which is used for manufacturing the spectrum chip 200 as described above. As mentioned above, in order to achieve mass production, the current spectrum chip 200 is manufactured by the following manufacturing process: firstly, a layer of a light modulation layer material is deposited on an existing image sensor (e.g., CMOS image sensor, CCD sensor); then, the light modulation layer material is etched to form the light modulation structure 112. However, this manufacturing process has many problems in practical industrial implementation.

Specifically, this process needs processing on the wafer of sensor corresponding to the existing CMOS image sensor or CCD sensor, and thus it is necessary to provide product lines and production teams that match the wafer-level processing, which will lead to an increase in costs on the one hand, and is difficult to be implemented in industry due to the monopoly of the processing technology of the wafer of sensor the other hand. In addition, the process of depositing the light modulation layer structure according to the characteristics of the material needs to be carried out under certain high temperature condition, however, the high temperature may cause damage to the wafer of sensor. Conversely, considering the heat resistance of the wafer of sensor, compromises must be made in the selection of the light modulation layer material, which will result in the light modulation layer not reaching the optimum performance due to the selection of the material. In addition, since the image sensor contains a logic circuit, metal powders may be generated to pollute the manufacturing environment.

In view of the above technical difficulties, the inventors of the present application tried to transfer the process of forming the light modulation structure 112 to be performed on the substrate 111, so as to get rid of the limitation of the existing manufacturing process of the spectrum chip 200 limited by the fab on the one hand, and on the other hand to ensure that the spectrum chip 200 will not be polluted during the manufacturing process. That is, the modulation unit 110 of the spectrum chip 200 is separately formed on the substrate 111 and then coupled to the sensor. In this way, the problem that the current manufacturing process of the spectrum chip 200 is limited by the fab is solved. Moreover, since the modulation unit 110 does not include a logic circuit, no contamination of metal powders and the like occur during the manufacturing process and further it can be ensured that no contamination occurs during processing process. At the same time, it can avoid high temperature affecting the performance of the sensor.

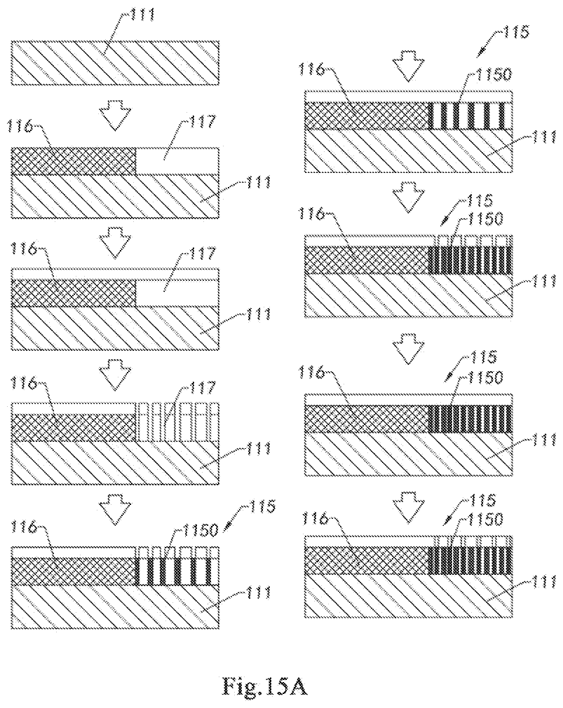

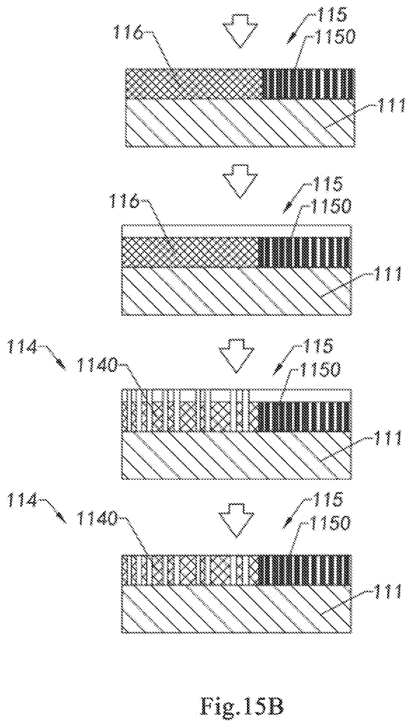

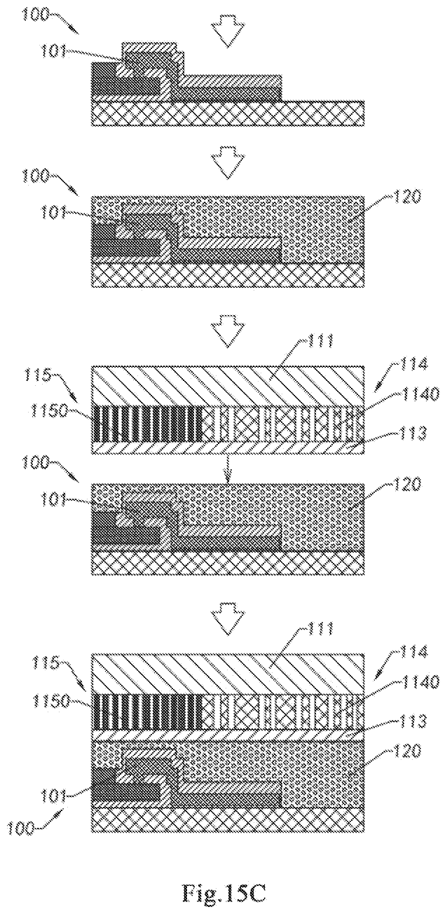

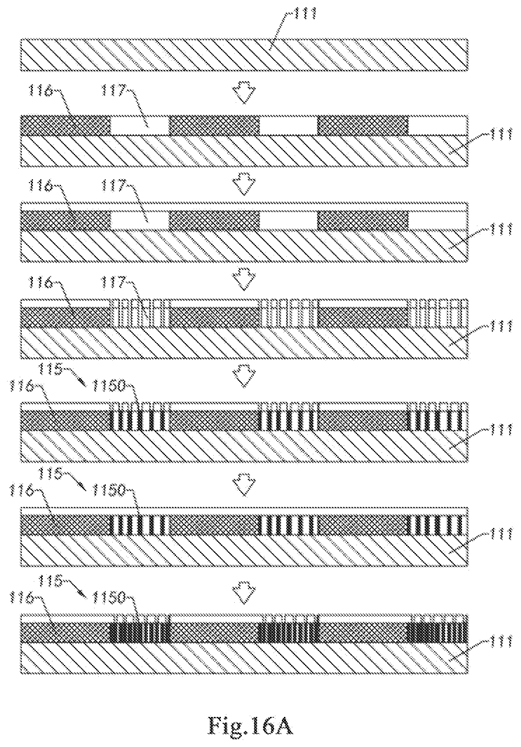

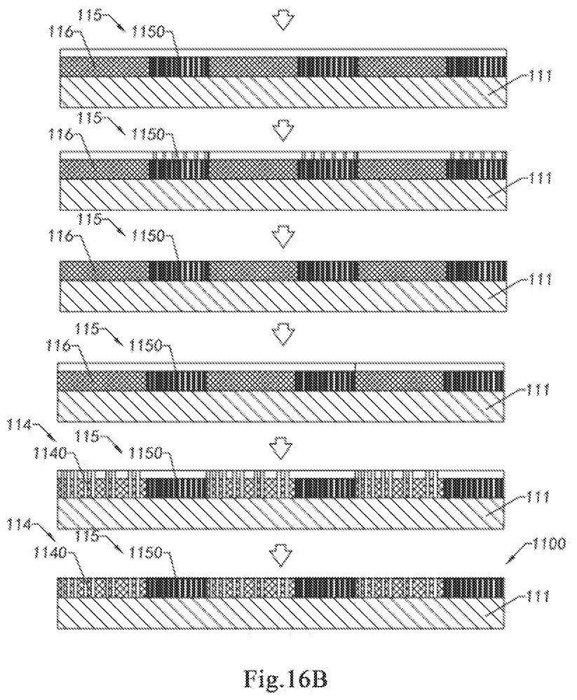

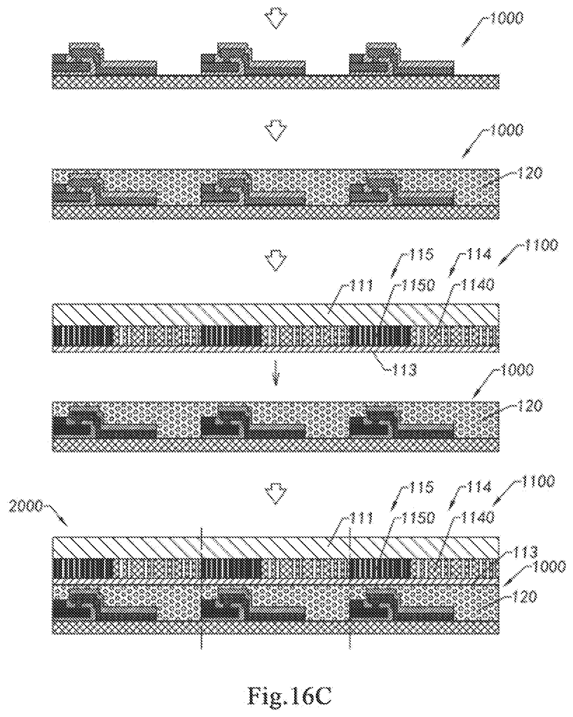

FIGS. 15A to 15C are schematic diagrams illustrating a method for manufacturing the spectrum chip 200 according to an example of the present application. As shown in FIGS. 15A to 15C, the manufacturing process of the spectrum chip 200 according to the example of the present application includes: firstly providing the substrate 111, wherein the substrate 111 is made of material selected from silicon dioxide or alumina or other transparent materials, such as quartz, sapphire, etc., or transparent organic materials, such as plastic, acrylic, etc., or metal materials, such as germanium.

Then, at least one light modulation structure 112 is formed on the substrate 111 to obtain the modulation unit 110, and the light modulation structure 112 includes the modulation portion 114 and the non-modulation portion 115. Correspondingly, in this example, the non-modulation portion 115 includes at least one filter unit 1150 and the filter unit 1150 constitutes a Bayer array.

Specifically, in this example, forming at least one light modulation structure 112 on the substrate 111 to obtain the modulation unit 110 includes: firstly forming a first material region 116 and a second material region 117 on the substrate 111, that is, forming materials for forming the modulation portion 114 and the non-modulation portion 115 on the substrate 111, respectively. It is worth mentioning that the first material region 116 and the second material region 117 may be formed of the same material or different materials, and the selected materials include but are not limited to: silicon, silicide, tantalum oxide, titanium dioxide, etc. More specifically, in a specific implementation, the first material region 116 and the second material region 117 may be formed on the substrate 111 by a deposition process which may be chemical vapor deposition (CVD), atomic layer deposition (ALD), plasma enhanced chemical vapor deposition (PECVD), physical vapor deposition (PVD), etc. . . . Furthermore, preferably, the first material region 116 and the second material region 117 have the same thickness dimension, and of course the thickness dimension of the two may also be different.

Here, when the first material region 116 and the second material region 117 have the same thickness and the same material, the first material region 116 and the second material region 117 are of the same layer of material. For the convenience of description, the same layer of material is named light modulation layer.

Next, the first material region 116 is processed to form the modulation portion 114, and the second material region 117 is processed to form the non-modulation portion 115. More specifically, a mask layer is firstly formed on the upper surfaces of the first material region 116 and the second material region 117, for example, a photoresist is laid on the upper surfaces of the first material region 116 and the second material region 117 to form the mask layer.

Then, a filling hole for forming the filter unit 1150 is formed by developing, exposing, etching and other processes and then is filled with a first filter material to form the filter unit 1150 of the non-modulation portion 115. Then, the old mask layer is removed and a new mask layer is formed, and again a filling hole for forming the filter unit 1150 is formed by developing, exposing, etching and other processes and then is filled with a second filter material to form the filter unit 1150 of the non-modulation portion 115. Then, again the old mask layer is removed and a new mask layer is formed, and a filling hole for forming the filter unit 1150 is formed by developing, exposing, etching and other processes and then is filled with a third filter material to form the filter unit 1150 of the non-modulation portion 115. That is, by repeating the process multiple times, the plurality of the filter units 1150 form a Bayer array.

Next, the old mask layer is removed again and a new mask layer is formed, and the first material region 116 is processed again by developing, exposing, etching and other processes to form the modulation portion 114 with at least one light modulation unit 1140.

Then, the mask layer is removed to obtain the modulation unit 110 as described above. It is worth mentioning that, optionally, a binding layer 113 may be formed on the surface of the modulation unit 110.

Next, a sensing unit 100 is provided. The sensing unit 100 includes at least one pixel unit 101, a logic circuit layer electrically connected to the pixel unit 101, and a memory electrically connected to the logic circuit layer. It is worth mentioning that, in some specific examples, the sensing unit 100 may also not include the memory, but only include the at least one pixel unit 101 and the logic circuit layer.

Next, the modulation unit 110 is coupled to the sensing unit 100, so that the modulation unit 110 is held on the photosensitive path of the sensing unit 100 to obtain the spectrum chip 200. In this example, the modulation unit 110 is coupled to the sensing unit 100 in a flip-chip manner, wherein at least one light modulation structure 112 of the modulation unit 110 is stacked on the sensing unit 100. In a specific example, the process of coupling the modulation unit 110 to the sensing unit 100 in the flip-chip manner includes: firstly, forming a dielectric layer 120 on the sensing unit 100, wherein preferably, the dielectric layer 120 is made of material with low refractive index; and then coupling the modulation unit 110 to the dielectric layer 120. Optionally, before coupling, the modulation unit 110 and/or the sensing unit 100 may be cleaned to remove surface particles.

In order to prevent the uneven lower surface of the light modulation structure 112 from causing poor binding to the sensing unit 100 (for example, low matching accuracy) and thus affecting the performance of the spectrum chip 200, in some examples of the present application, a binding layer 113 may also be formed on at least one light modulation structure 112 of the modulation unit 110; and then, the modulation unit 110 is coupled to the dielectric layer 120 in a manner that the binding layer 113 is bound to the dielectric layer 120. Preferably, the binding layer 113 and the dielectric layer 120 have the similar refractive index, and more preferably both are made of the same material (for example, both are made of silicon dioxide).

It is worth mentioning that, in this example, a distance a between the lower surface of the light modulation structure 112 and the upper surface of the dielectric layer 120 is limited, because when the distance is too large, it is easy to cause crosstalk of light, that is, the light modulated by the light modulation structure 112 has a certain divergence angle, and if the distance a is too large, the modulated light will enter the pixel unit 101 corresponding to the adjacent light modulation structure 112, thereby resulting in inaccurate information received by pixel unit 101 and further poor recovery accuracy. Further, preferably, the distance is less than or equal to twice the length of side b of the light modulation structure 112, that is, a≤2b, wherein the light modulation structure 112 is composed of a plurality of light modulation units 1140, each of which has a corresponding period, the shape and size of the modulation unit 110 may be defined according to the period of the light modulation unit 1140, such as being a square or a rectangle, and the distance is less than or equal to twice the length of the short side of the rectangle or twice the length of side of the square. In the case of high accuracy requirements, the distance a may be less than or equal to the length of side b, that is, a≤b. Further, too large distance a easily leads to the poor uniformity of the gap between the two. Preferably, the gap a is less than or equal to 10 um. It is understandable that some gaps larger than 10 um due to manufacturing errors are also within the scope of protection of the present application, that is, the distance between the lower surface of the light modulation structure 112 and the upper surface of the dielectric layer 120 is less than or equal to 10 um, however, it is not required that the gap corresponding to anyone of the positions on the light modulation structure 112 and the dielectric layer 120 meets this requirement. It may be that some positions meet the requirement, but preferably it is ensured that at least 90% of the regions meet this requirement. More preferably, the distance between the lower surface of the light modulation structure 112 and the upper surface of the dielectric layer 120 is less than or equal to 5 um, for example, 2.5 um. Further, in order to ensure the performance of the spectrum chip 200, the difference in distances between any two regions in the lower surface of the light modulation structure 112 and the upper surface of the dielectric layer 120 is less than or equal to 10 um, preferably less than or equal to 5 um, thereby ensuring uniformity. It is also worth mentioning that, in this example, preferably, the binding layer 113 and the dielectric layer 120 have the similar refractive index, and more preferably both are made of the same material (for example, both are made of silicon dioxide). At the same time, the introduction of the binding layer 113 can also ensure the uniformity of the gap between the sensing unit 100 and the modulation unit 110, thereby helping to suppress interference fringes and their effects.

In order to enable mass production, a jointed panel process may be implemented for the sensing units 100, that is, the sensing unit jointed panel 1000 has at least two sensing units 100, wherein the sensing unit 100 may be a CMOS, CCD, indium gallium arsenide sensor, and a modulation sensor with a filter structure such as quantum dots or nanowires on the upper surface; and then a dielectric layer 120 is formed on the surfaces of the sensing units 100 by a process such as deposition, and the upper surface of the dielectric layer 120 is flattened. Correspondingly, at least two light modulation structures 112 are formed on the substrate 111 to form a modulation unit jointed panel 1100, and then the modulation unit jointed panel 1100 is applied to the flat dielectric layer 120 on the sensing unit jointed panel to obtain a semi-finished spectrum chip 2000, wherein the light modulation structures 112 of the modulation units 110 are aligned with the corresponding sensing units 100, and then the semi-finished spectrum chip 2000 is cut to obtain the spectrum chips 200.

Here, the substrate 111 may be implemented as quartz, sapphire, etc. The light modulation layer material may be deposited on the surface of the substrate 111, and then the light modulation structure 112 is formed by nano-imprinting, etching, etc. The modulation unit jointed panel 1100 may be understood as a plurality of identical modulation units 110 formed on a substrate 111, and each modulation unit 110 and the corresponding sensing unit 100 constitute a modulation unit pixel.

That is, in this example of the present application, the method for manufacturing the spectrum chip 200 includes steps of: firstly, providing a substrate 111; next, forming an array of light modulation structures 112 on the substrate 111 to obtain a modulation unit jointed panel 1100, wherein the array of the light modulation units 1140 includes at least two light modulation structures 112; then, providing a sensing unit jointed panel 1000 which includes at least two sensing units 100; then, coupling the modulation unit jointed panel 1100 to the sensing unit jointed panel 1000 to obtain the jointed panel of the spectrum chip 200, wherein optionally, before the coupling, the modulation unit jointed panel 1100 and/or the sensing unit jointed panel are cleaned to remove surface particles; finally, dividing the jointed panel of the spectrum chip 200 to obtain at least two spectrum chips 200.

Further, in a variant example, the difference from the example 5 is as follows. That is, the second material region 117 corresponding to the non-modulation portion 115 may be engraved through, or may not be processed. Non-modulation portion 115 implemented as a Bayer array is also taken as an example, the Bayer array may be preset on the sensing unit 100. In this case, only a light modulation layer is formed on the substrate 111, and then the first material region 116 is processed to obtain the modulation portion 114. In the variant example, since the Bayer array has been formed in the sensing unit 100, the second material region 117 may not be processed or hollowed out.

### Example 6

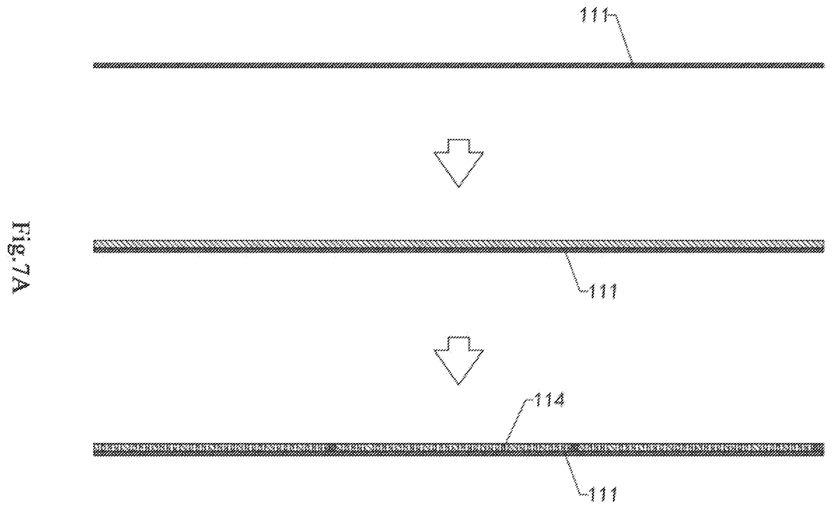

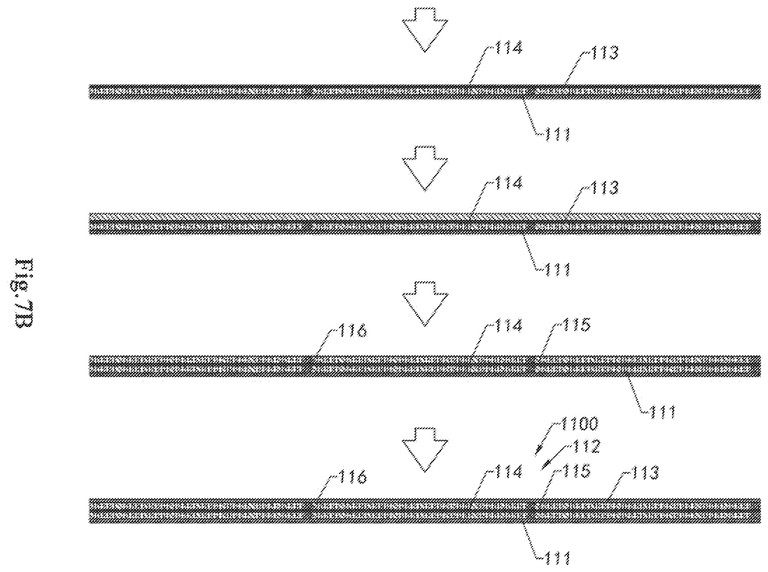

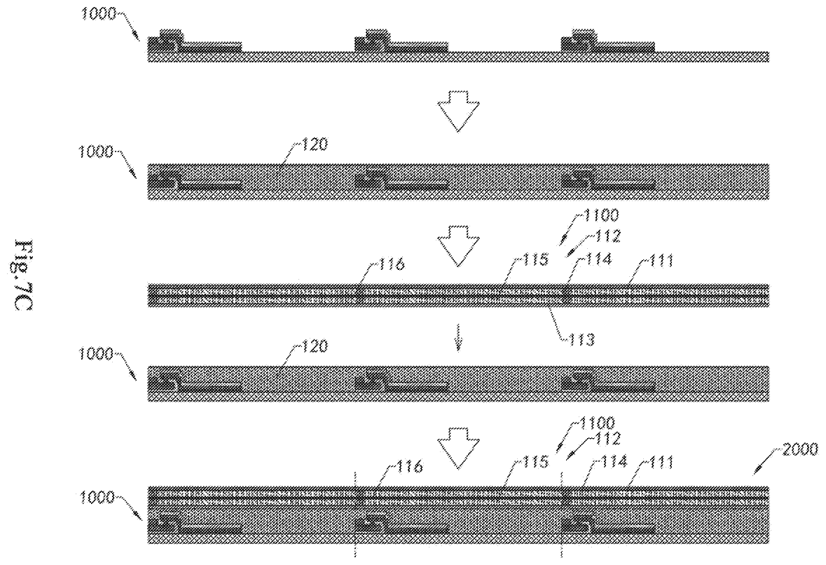

The difference from example 5 is that the sensing unit 100 and the modulation unit 110 are only implemented to be simply fitted together, with van der Waals forces formed between them. Preferably, after the spectrum chip 200 is formed and affixed to the circuit board 310, an encapsulation body 130 is formed on the surface of the circuit board and the side and/or surface of the spectrum chip 200. The circuit board 310, the spectrum chip 200 and the encapsulation body 130 are in an integrated structure by the encapsulation body 130, as shown in FIG. 7. In individual examples, the encapsulation body 130 does not need to be matched with the circuit board, that is, the encapsulation body 130 is fitted with the sensing unit 100 and the modulation unit 110, so that the sensing unit 100 and the modulation unit 110 are fixed by the encapsulation body 130.

Further, the encapsulation body 130 serves to fix the sensing unit 100 and the modulation unit 110 of the spectrum chip 200 in this example. In this example, the sensing unit 100 and the modulation unit 110 are directly fitted, and the fixing of the modulation unit 110 and the sensing unit 100 is realized by the encapsulation body 130. That is, in this example, the sensing unit 100 and the modulation unit 110 do not need to be bonded or adhered by an adhesive, so that it is ensured that the gap between the two is less than or equal to 2.5 μm, and at the same time, the refractive index change caused by the adhesive and other problems can be avoided to a certain extent. It is worth mentioning that the encapsulation body 130 is equivalent to a bracket in the spectrum analysis device, and may be used to support the optical module 320 and the like.

Further, the encapsulation body 130 may be formed by a molding process. That is, the jointed panel of the circuit board 310 and the spectrum chip 200 are assembled and electrical conduction is achieved, and then placed in a mold, and then a molding material is injected. The mold is opened after curing, and the spectrum chip 200 is obtained by cutting. It is also possible to set a mold on the spectrum chip 200 and the circuit board 310, and then inject the adhesive into the mold. The encapsulation body 130 is formed after the adhesive is cured.

Of course, it is also possible to directly fix the spectrum chip 200 by the encapsulation body 130 obtained by processing using gluing and the like. It is worth mentioning that in this example, how the encapsulation body 130 is disposed and formed is not limited, and it only needs to realize that the spectrum chip 200, the circuit board 310 and the encapsulation body 130 can be formed into one piece by the encapsulation body 130, to improve the reliability of the spectrum analysis device. Alternatively, the encapsulation body 130 can play the role of fixing the sensing unit 100 and the modulation unit 110.

Further, in this example, the encapsulation body 130 includes a main body and a fixing part integrally extending inward from the main body, and the adhesive is provided on the fixing part and the bottom of the main body of the encapsulation body 130, so that the fixing part is adhered to the upper surface of the substrate 111 of the modulation unit 110, and the bottom of the main body is adhered to the circuit board 310 by the adhesive. Therefore, the spectrum chip 200, the circuit board 310 and the encapsulation body 130 are formed into one piece by the encapsulation body 130.

It is worth mentioning that, preferably, the side wall of the main body clings to the side wall of the spectrum chip 200, so as to prevent horizontal sliding. Preferably, the encapsulation body 130 is made of an opaque material, so that the encapsulation body 130 can also prevent stray light from entering the spectrum chip 200 from the side of the modulation unit 110, thereby causing noise to reduce the accuracy.

### Example 7

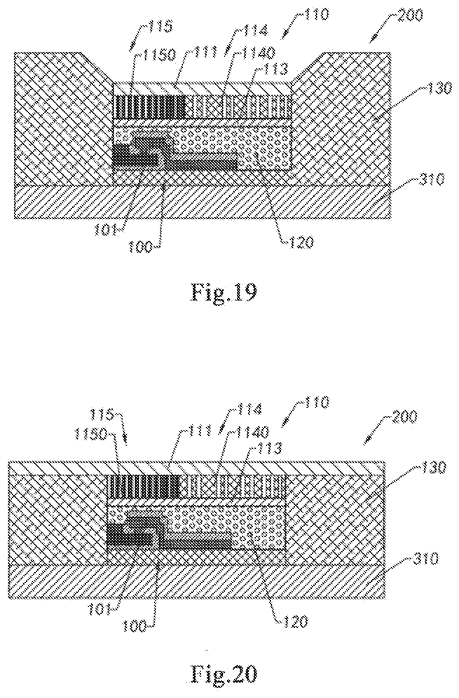

As shown in FIG. 19, the present application also provides a photosensitive component, which includes a circuit board 310 and a spectrum chip 200 electrically connected to the circuit. The photosensitive component includes an encapsulation body 130 which is formed on the surface of the circuit board 310 and surrounds the sensing unit 100 of the spectrum chip 200.

Preferably, the photosensitive component is obtained by the following. Firstly, the sensing unit 100 of the spectrum chip 200 is affixed to the circuit board 310 and electrical conduction is achieved (COB and CSP are both acceptable), preferably there is a dielectric layer 120 with a flat upper surface on the surface of the sensing unit 100. Then the encapsulation body 130 is formed on the non-photosensitive region of the sensing unit 100 and the surface of the circuit board 310 by processes such as molding and affixing, that is, it can be understood that the sensing unit 100, the circuit board 310 and the encapsulation body 130 are in an integrated structure. Then the modulation unit 110 is affixed to the surface of the sensing unit 100 to obtain the photosensitive component. Further, a distance between the lower surface of the light modulation structure 112 of the modulation unit 110 and the upper surface of the dielectric layer 120 of the sensing unit 100 is less than or equal to 2.5 μm. Preferably, the modulation unit 110 and the encapsulation body 130 are fixed by an adhesive. It is worth mentioning that the thickness of the adhesive is less than or equal to 2.5 μm, and preferably, the refractive index of the adhesive may be the same as that of the dielectric layer 120 or the light modulation layer, so as to prevent the generation of equal thickness interference.

Preferably, a jointed panel process may also be performed in this example. That is, a circuit board jointed panel is provided, and the sensing units 100 are respectively affixed to the circuit boards, preferably, there is a dielectric layer 120 with a flat upper surface on the surfaces of the sensing units 100. Then an encapsulation body 130 is formed on the circuit boards and the non-photosensitive regions of the sensing units 100 by molding, pasting, etc. . . . Then the modulation unit jointed panel 1100 is affixed to the circuit board imposition, and the modulation units 110 are aligned with the sensing units 100 to form a plurality of pixels of the modulation unit 110. Optionally, the modulation unit 110 and the sensing unit 100 may be cleaned to remove surface particles before they are bound. It is worth mentioning that the surface of the encapsulation body 130 is generally flat, and an adhesive may be coated on the surface of the encapsulation body 130. Since there is a certain distance between modulation units 110 of the modulation unit jointed panel 1100, that is, there is an affixing region between the modulation units 110, the affixing region of the modulation unit jointed panel 1100 is adhered to the encapsulation body 130 by the adhesive on the encapsulation body 130 after the modulation unit jointed panel 1100 is affixing to the circuit board jointed panel, so that the circuit board jointed panel and the modulation unit jointed panel 1100 are fixed to obtain the photosensitive module jointed panel which is then is cut to obtain photosensitive component.

Optionally, the photosensitive component further includes a light shielding member, which is formed on the side and the surface edge of the substrate 111 to prevent stray light from entering the sensing unit 100.

### Example 8

The difference from the example 7 is that, as shown in FIG. 20, in this example, the encapsulation body 130 does not wrap the sensing unit 100. That is, the encapsulation body 130 having a light-passing port (also provided in all of the previous examples) is firstly formed on the circuit board 310, and then the sensing unit 100 is affixed to the circuit board 310 through the light-passing port and the conduction is realized. Then the modulation unit jointed panel 1100 is affixed to the circuit board jointed panel, and the upper surface of the encapsulation body 130 is provided with an adhesive for adhering the affixing region of the modulation unit jointed panel 1100. Then, the photosensitive module jointed panel is cut to obtain the photosensitive components. At this time, an adhesive may be applied between the modulation unit 110 and the sensing unit 100.

For the examples 3 and 4, the modulation unit 110 may also be individually affixed to the surface of each sensing unit 100. In addition, it should be noted that the distance between the upper surface of the dielectric layer 120 of the modulation unit 110 and the lower surface of the light modulation structure 112 of the modulation unit 110 is less than or equal to 2.5 μm. Therefore, when designing, the height c of the light modulation structure 112 needs to be set according to the distance a between the upper surface of the encapsulation body 130 and the upper surface of the dielectric layer 120, as well as the thickness b of the adhesive disposed on the upper surface of the encapsulation body 130, that is, a+b−c≤2 μm.

In particular, it should be noted that in the present application, the substrate 111 is located above the light modulation structure 112 to cover the light modulation structure 112, so as to protect the light modulation structure 112 and the sensing unit 100.

The basic principles of the present application have been described above in combination with specific examples. However, it should be pointed out that the merits, advantages, effects, etc. mentioned in the present application are only examples and are not limiting, and these merits, advantages, effects, etc., cannot be considered to be required for each example of the present application. In addition, the specific details disclosed above are only for the purpose of example and easy understanding, and are not limiting. The above-mentioned details do not limit the present application to be implemented by using the above-mentioned specific details.

1-59. (canceled)

60. A method for manufacturing a spectrum chip, characterized by comprising:
forming an array of light modulation structures including at least two light modulation structures on a substrate to obtain a modulation unit jointed panel;
providing a sensing unit jointed panel which includes at least two sensing units;
coupling the modulation unit jointed panel to the sensing unit jointed panel to obtain a spectrum chip jointed panel; and
dividing the spectrum chip jointed panel to obtain at least two spectrum chips.

61. The method for manufacturing the spectrum chip according to claim 60, wherein the at least one light modulation structure includes a first light modulation structure and a second light modulation structure;
and forming the at least one light modulation structure on the substrate to obtain the modulation unit includes:
forming a first light modulation layer on the substrate;
etching or nano-imprinting the first light modulation layer to form the first light modulation structure with at least one first modulation unit;
forming a second light modulation layer on the first light modulation structure; and
etching or nano-imprinting the second light modulation layer to form the second light modulation structure with at least one second modulation unit.

62. The method for manufacturing the spectrum chip according to claim 60, wherein the at least one modulation unit includes a first light modulation structure;
and forming the at least one light modulation structure on the substrate to obtain the modulation unit including:
forming a first light modulation layer on the substrate; and
etching or nano-imprinting the first light modulation layer to form the first light modulation structure with at least one first modulation unit.

63. The method for manufacturing the spectrum chip according to claim 61, wherein forming the first light modulation layer on the substrate includes:
depositing the first light modulation layer on the substrate by a deposition process.

64. The method for manufacturing the spectrum chip according to claim 61, wherein forming the first light modulation layer on the substrate includes:
providing the first light modulation layer; and
overlaying the light modulation layer on the substrate.

65. The method for manufacturing the spectrum chip according to claim 61, wherein forming the second light modulation layer on the first light modulation structure includes:
forming a connection layer on the first light modulation layer; and
forming the second light modulation layer on the connection layer.

66. The method for manufacturing the spectrum chip according to claim 60, wherein coupling the modulation unit to the sensing unit, so that the modulation unit is held on the photosensitive path of the sensing unit to obtain the spectrum chip includes:
coupling the modulation unit to the sensing unit in a flip-chip manner, wherein at least one light modulation structure of the modulation unit is overlaid on the sensor.

67. The method for manufacturing the spectrum chip according to claim 66, wherein coupling the modulation unit to the sensing unit in the flip-chip manner includes:
forming a dielectric layer on the sensing unit; and
coupling the modulation unit to the dielectric layer.

68. The method for manufacturing the spectrum chip according to claim 67, wherein coupling the modulation unit to the dielectric layer includes:
forming a binding layer on the at least one light modulation structure of the modulation unit; and
coupling the modulation unit to the dielectric layer in a manner that the binding layer is bound to the dielectric layer.

69. The method for manufacturing the spectrum chip according to claim 60, wherein coupling the modulation unit to the sensing unit, so that the modulation unit is held on the photosensitive path of the sensing unit to obtain the spectrum chip includes:
attaching the modulation unit to the sensing unit by van der Waals forces; or
attaching the modulating unit to the sensing unit by an adhesive; or
attaching the modulation unit to the sensing unit by a bonding process.

70. The method for manufacturing the spectrum chip according to claim 67, wherein a distance between a lower surface of the light modulation structure adjacent to the sensing unit in the at least one light modulation structure and an upper surface of the dielectric layer is less than or equal to 10 um.

71. The method for manufacturing the spectrum chip according to claim 70, wherein a proportion of the distance between the lower surface of the light modulation structure adjacent to the sensing unit in the at least one light modulation structure and the upper surface of the dielectric layer exceeding a preset threshold is less than or equal to 10%.

72. The method for manufacturing the spectrum chip according to claim 71, wherein a difference in distances between respective corresponding positions on the lower surface of the light modulation structure adjacent to the sensing unit in the at least one light modulation structure and the upper surface of the dielectric layer is less than 10 um.

73. The method for manufacturing the spectrum chip according to claim 67, wherein the light modulation structure includes at least one light modulation unit, wherein the distance between the lower surface of the light modulation structure adjacent to the sensing unit in the at least one light modulation structure and the upper surface of the dielectric layer is less than a length of a side of the light modulation unit.

74. The method for manufacturing the spectrum chip according to claim 67, wherein a difference in distances between any two regions in the lower surface of the light modulation structure adjacent to the sensing unit in the at least one light modulation structure and two corresponding regions in the upper surface of the dielectric layer is less than or equal to 10 um.

75. The method for manufacturing the spectrum chip according to claim 60, wherein the light modulation structure includes a modulation portion and a non-modulation portion.

76. The method for manufacturing the spectrum chip according to claim 75, wherein the modulation portion includes at least one light modulation unit, and the non-modulation portion includes at least one filter unit.

77. The method for manufacturing the spectrum chip according to claim 76, wherein forming the at least one light modulation structure on the substrate to obtain the modulation unit includes:
forming a light modulation layer on the substrate;
forming the modulation portion in a partial region of the light modulation layer; and
forming the non-modulation portion in other partial regions of the light modulation layer.

78. A method for manufacturing a spectrum chip, characterized by comprising:
forming at least one light modulation structure on a substrate to obtain a modulation unit; and
coupling the modulation unit to a sensing unit, so that the modulation unit is held on a photosensitive path of the sensing unit to obtain a spectrum chip.

79. A spectrum chip manufactured by the method for manufacturing the spectrum chip according to claim 60.

80. The spectrum chip according to claim 79, wherein the modulation unit and the sensing unit are bound with each other by a van der Waals force under the action of the encapsulation body.

81. A spectrum analysis device, characterized by comprising:
a circuit board; and
a spectrum chip manufactured by the method for manufacturing the spectrum chip according to claim 60, wherein the spectrum chip is electrically connected to the circuit board.

82. The spectrum analysis device according to claim 81, further including: an optical module held on a photosensitive path of the spectrum chip.

83. The spectrum analysis device according to claim 81, further including an encapsulation body disposed on the circuit board, wherein the encapsulation body is integrally formed on the circuit board and covers at least a part of an outer surface of the spectrum chip.

84. The spectrum analysis device according to claim 83, wherein the encapsulation body is made of an opaque material.
